(19) United States
(12) Patent Application Publication
(10) Pub. No.: US 2021/0159373 A1
(43) Pub. Date: May 27, 2021

(54) LIGHT EXTRACTION FOR MICRO-LEDS

(71) Applicant: Facebook Technologies, LLC, Menlo Park, CA (US)

(72) Inventor: Michael GRUNDMANN, Kirkland, WA (US)

(21) Appl. No.: 16/953,714

(22) Filed: Nov. 20, 2020

Related U.S. Application Data
(60) Provisional application No. 62/939,302, filed on Nov. 22, 2019.

(51) Int. Cl. H01L 33/58; G02B 3/00; G02B 3/04; H01L 27/15; H01L 33/24; H01L 33/46; H01L 33/62; H01L 23/00

(52) U.S. Cl. CPC H01L 33/58; H01L 2224/80896; G02B 3/04; G02B 3/0018; H01L 27/156; H01L 33/24; H01L 33/46; H01L 33/62; H01L 24/08; H01L 24/80; H01L 2933/0058; H01L 2933/0066; H01L 2224/08145; H01L 2224/80895; G02B 3/0043

(57) ABSTRACT

Techniques disclosed herein relate to light extraction structures for micro-LED arrays. According to certain embodiments, a device includes an array of micro-LEDs characterized by a first pitch, and an array of micro-lenses on the array of micro-LEDs and characterized by a second pitch different from the first pitch. Each micro-lens in the array of micro-lenses corresponds to a respective micro-LED in the array of micro-LEDs. In some embodiments, the first pitch is greater than the second pitch such that a chief ray of light from each micro-LED in the array of micro-LEDs after passing through the corresponding micro-lens tilts in a respective direction towards a middle line of the device.

### CROSS-REFERENCE TO RELATED APPLICATION

This application claims the benefit of and priority to U.S. Provisional Application No. 62/939,302, filed Nov. 22, 2019, entitled “LIGHT EXTRACTION FOR MICRO-LEDS,” which is incorporated herein by reference in its entirety for all purposes.

### BACKGROUND

Light emitting diodes (LEDs) convert electrical energy into optical energy, and offer many benefits over other light sources, such as reduced size, improved durability, and increased efficiency. LEDs can be used as light sources in many display systems, such as televisions, computer monitors, laptop computers, tablets, smartphones, projection systems, and wearable electronic devices. Micro-LEDs (“LEDs”) based on III-nitride semiconductors, such as alloys of AlN, GaN, InN, and the like, have begun to be developed for various display applications due to their small size (e.g., with a linear dimension less than 100 μm, less than 50 μm, less than 10 μm, or less than 5 μm), high packing density (and hence higher resolution), and high brightness. For example, micro-LEDs that emit light of different colors (e.g., red, green, and blue) can be used to form the sub-pixels of a display system, such as a television or a near-eye display system.

### SUMMARY

This disclosure relates generally to micro light emitting diodes (micro-LEDs). More specifically, this disclosure relates to a micro-lens array for light extraction from a micro-LED array. According to certain embodiments, a device may include an array of micro-LEDs characterized by a first pitch, and an array of micro-lenses on the array of micro-LEDs and characterized by a second pitch different from the first pitch. Each micro-lens in the array of micro-lenses may correspond to a respective micro-LED in the array of micro-LEDs.

In some embodiments, each micro-lens in the array of micro-lenses may be configured such that a chief ray of light from each corresponding micro-LED in the array of micro-LEDs after passing through the micro-lens may propagate in a different respective direction. In some embodiments, the first pitch may be greater than the second pitch, such that a chief ray of light from each micro-LED in the array of micro-LEDs after passing through the corresponding micro-lens may tilt in a respective direction towards a middle line of the device. In some embodiments, the first pitch may be lower than the second pitch. In some embodiments, the first pitch may be less than about 10 μm. In some embodiments, a linear dimension of each micro-lens in the array of micro-lenses may be greater than a linear dimension of each micro-LED in the array of micro-LEDs.

In some embodiments, the array of micro-LEDs may include a two-dimensional array of micro-LEDs, the array of micro-lenses may include a two-dimensional array of micro-lenses, and the first pitch and the second pitch may be in a first dimension. In some embodiments, the array of micro-LEDs may be characterized by a third pitch in a second dimension, the array of micro-lenses may be characterized by a fourth pitch in the second dimension, and the third pitch may be different from the fourth pitch. In some embodiments, the first pitch may be different from the third pitch. In some embodiments, the second pitch may be different from the fourth pitch.

In some embodiments, the array of micro-lenses may include a dielectric material or an organic material. The dielectric material may include, for example, silicon oxide or silicon nitride. In some embodiments, the array of micro-lenses may include an anti-reflective coating. In some embodiments, the array of micro-lenses may include spherical micro-lenses or aspherical micro-lenses. In some embodiments, each micro-lens in the array of micro-lenses may be configured to collimate light from the corresponding micro-LED in the array of micro-LEDs. In some embodiments, at least one of the first pitch or the second pitch may vary across the device.

According to certain embodiments, a method may include depositing a polymer layer on a dielectric layer of a micro-LED array, patterning the polymer layer to form a polymer pattern, and reflowing the polymer pattern to form a micro-lens array in the polymer layer. The micro-LED array may be characterized by a first pitch between centers of adjacent micro-LEDs, the polymer pattern in the polymer layer may be characterized by a second pitch different from the first pitch, and the micro-lens array may be characterized by a third pitch equal to the second pitch. In some embodiments, the method may further include etching the micro-lens array in the polymer layer and the dielectric layer of the micro-LED array to form a micro-lens array in the dielectric layer, where the polymer layer may be characterized by an etch rate comparable to an etch rate of the dielectric layer.

In some embodiments, the method may also include depositing an antireflective layer on the micro-lens array in the dielectric layer. In some embodiments, the method may include planarizing the dielectric layer prior to depositing the polymer layer. In some embodiments, the polymer layer may include a photoresist layer, and patterning the polymer layer may include exposing the photoresist layer to exposure light through a gray-scale mask or a binary mask, and developing the photoresist layer using a photoresist developer to remove exposed portions of the photoresist layer. The light transmissivity profile of the gray-scale mask may be complementary to a height profile of the micro-lens array in the polymer layer. The binary mask may be characterized by a light transmissivity pattern corresponding to the polymer pattern in the polymer layer.

This summary is neither intended to identify key or essential features of the claimed subject matter, nor is it intended to be used in isolation to determine the scope of the claimed subject matter. The subject matter should be understood by reference to appropriate portions of the entire specification of this disclosure, any or all drawings, and each claim. The foregoing, together with other features and examples, will be described in more detail below in the following specification, claims, and accompanying drawings.

### BRIEF DESCRIPTION OF THE DRAWINGS

Illustrative embodiments are described in detail below with reference to the following figures.

FIG. 1 is a simplified block diagram of an example of an artificial reality system environment including a near-eye display according to certain embodiments.

FIG. 2 is a perspective view of an example of a near-eye display in the form of a head-mounted display (HMD) device for implementing some of the examples disclosed herein.

FIG. 3 is a perspective view of an example of a near-eye display in the form of a pair of glasses for implementing some of the examples disclosed herein.

FIG. 4 illustrates an example of an optical see-through augmented reality system including a waveguide display according to certain embodiments.

FIG. 5A illustrates an example of a near-eye display device including a waveguide display according to certain embodiments. FIG. 5B illustrates an example of a near-eye display device including a waveguide display according to certain embodiments.

FIG. 6 illustrates an example of an image source assembly in an augmented reality system according to certain embodiments.

FIG. 7A illustrates an example of a light emitting diode (LED) having a vertical mesa structure according to certain embodiments. FIG. 7B is a cross-sectional view of an example of an LED having a parabolic mesa structure according to certain embodiments.

FIG. 8 illustrates an example of a device including a micro-LED array and an array of micro-lenses for light extraction from the micro-LED array.

FIG. 9 illustrates an example of a device including a micro-LED array and an array of micro-lenses for extraction and converging light from the micro-LED array according to certain embodiments.

FIG. 10 illustrates an example of a device including a micro-LED array and an array of micro-lenses for extraction and diverging light from the micro-LED array according to certain embodiments.

FIG. 11 illustrates an example of a two-dimensional array of micro-lenses for light extraction from a two-dimensional micro-LED array according to certain embodiments.

FIGS. 12A-12D illustrate an example of a method for fabricating an array of micro-lenses for light extraction from a micro-LED array according to certain embodiments.

FIGS. 13A-13D illustrate an example of a method for fabricating an array of micro-lenses for light extraction from a micro-LED array according to certain embodiments.

FIG. 14 is a flow chart illustrating an example of a method for fabricating an array of micro-lenses for light extraction from a micro-LED array according to certain embodiments.

FIG. 15A illustrates an example of a method of die-to-wafer bonding for arrays of LEDs according to certain embodiments. FIG. 15B illustrates an example of a method of wafer-to-wafer bonding for arrays of LEDs according to certain embodiments.

FIGS. 16A-16D illustrates an example of a method of hybrid bonding for arrays of LEDs according to certain embodiments.

FIG. 17 illustrates an example of an LED array with secondary optical components fabricated thereon according to certain embodiments.

FIG. 18 is a simplified block diagram of an electronic system of an example of a near-eye display according to certain embodiments.

The figures depict embodiments of the present disclosure for purposes of illustration only. One skilled in the art will readily recognize from the following description that alternative embodiments of the structures and methods illustrated may be employed without departing from the principles, or benefits touted, of this disclosure.

In the appended figures, similar components and/or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

### DETAILED DESCRIPTION

This disclosure relates generally to light emitting diodes (LEDs). More specifically, and without limitation, disclosed herein are techniques for extracting light from a micro-LED array using a micro-lens array. The micro-lens array may be used to extract light from a micro-LED array and direct the light to desired directions in the display system, such as coupling light to a waveguide in a waveguide-based display system. According to certain embodiments, the micro-lens array may be characterized by a pitch different from the pitch of the micro-LED array in at least one dimension such that the offset between the center of a micro-lens and the center of a corresponding micro-LED may vary across the micro-lens array in the at least one dimension. As such, light from each micro-LED can be collimated (or focused or expanded) by a respective micro-lens, and the propagation direction of the chief ray of the light extracted from each micro-LED can be different across the array due to the different offsets. Thus, light from the micro-LED array can be more efficiently extracted, collimated (or focused or expanded), and directed to the desired directions in the projection system. The pitch between the micro-lenses can be uniform or non-uniform.

The micro-lens array can be fabricated using various techniques, such as reflowing patterned polymers (e.g., photoresist) or using a gray-scale photomask and a photoresist with a linear response to exposure dosage to form the micro-lens array in the photoresists, and/or dry etching the polymers or the photoresist to transfer the pattern and shape of the micro-lens array to a dielectric material layer (e.g., a substrate or an oxide layer). Various inventive embodiments are described herein, including devices, systems, methods, materials, processes, and the like.

The micro-LEDs and micro-lenses described herein may be used in conjunction with various technologies, such as an artificial reality system. An artificial reality system, such as a head-mounted display (HMD) or heads-up display (HUD) system, generally includes a display configured to present artificial images that depict objects in a virtual environment. The display may present virtual objects or combine images of real objects with virtual objects, as in virtual reality (VR), augmented reality (AR), or mixed reality (MR) applications. For example, in an AR system, a user may view both displayed images of virtual objects (e.g., computer-generated images (CGIs)) and the surrounding environment by, for example, seeing through transparent display glasses or lenses (often referred to as optical see-through) or viewing displayed images of the surrounding environment captured by a camera (often referred to as video see-through). In some AR systems, the artificial images may be presented to users using LED-based display subsystem.

As used herein, the term “light emitting diode (LED)” refers to a light source that includes at least an n-type semiconductor layer, a p-type semiconductor layer, and a light emitting region (i.e., active region) between the n-type semiconductor layer and the p-type semiconductor layer. The light emitting region may include one or more semiconductor layers that form one or more heterostructures, such as quantum wells. In some embodiments, the light emitting region may include multiple semiconductor layers that form one or more multiple-quantum-wells (MQWs) each including multiple (e.g., about 2 to 8) quantum wells.

As used herein, the term “micro-LED” or “LED” refers to an LED that has a chip where a linear dimension of the chip is less than about 200 μm, such as less than 100 μm, less than 50 μm, less than 20 μm, less than 10 μm, or smaller. For example, the linear dimension of a micro-LED may be as small as 6 μm, 5 μm, 4 μm, 2 μm, or smaller. Some micro-LEDs may have a linear dimension (e.g., length or diameter) comparable to the minority carrier diffusion length. However, the disclosure herein is not limited to micro-LEDs, and may also be applied to mini-LEDs and large LEDs.

As used herein, the term “bonding” may refer to various methods for physically and/or electrically connecting two or more devices and/or wafers, such as adhesive bonding, metal-to-metal bonding, metal oxide bonding, wafer-to-wafer bonding, die-to-wafer bonding, hybrid bonding, and the like. For example, adhesive bonding may use a curable adhesive (e.g., an epoxy) to physically bond two or more devices and/or wafers through adhesion. Metal-to-metal bonding may include, for example, wire bonding or flip chip bonding using soldering interfaces (e.g., pads or balls), conductive adhesive, or welded joints between metals. Metal oxide bonding may form a metal and oxide pattern on each surface, bond the oxide sections together, and then bond the metal sections together to create a conductive path. Wafer-to-wafer bonding may bond two wafers (e.g., silicon wafers or other semiconductor wafers) without any intermediate layers and is based on chemical bonds between the surfaces of the two wafers. Wafer-to-wafer bonding may include wafer cleaning and other preprocessing, aligning and pre-bonding at room temperature, and annealing at elevated temperatures, such as about 250° C. or higher. Die-to-wafer bonding may use bumps on one wafer to align features of a pre-formed chip with drivers of a wafer. Hybrid bonding may include, for example, wafer cleaning, high-precision alignment of contacts of one wafer with contacts of another wafer, dielectric bonding of dielectric materials within the wafers at room temperature, and metal bonding of the contacts by annealing at, for example, 250-300° C. or higher.

In the following description, for the purposes of explanation, specific details are set forth in order to provide a thorough understanding of examples of the disclosure. However, it will be apparent that various examples may be practiced without these specific details. For example, devices, systems, structures, assemblies, methods, and other components may be shown as components in block diagram form in order not to obscure the examples in unnecessary detail. In other instances, well-known devices, processes, systems, structures, and techniques may be shown without necessary detail in order to avoid obscuring the examples. The figures and description are not intended to be restrictive. The terms and expressions that have been employed in this disclosure are used as terms of description and not of limitation, and there is no intention in the use of such terms and expressions of excluding any equivalents of the features shown and described or portions thereof. The word “example” is used herein to mean “serving as an example, instance, or illustration.” Any embodiment or design described herein as “example” is not necessarily to be construed as preferred or advantageous over other embodiments or designs.

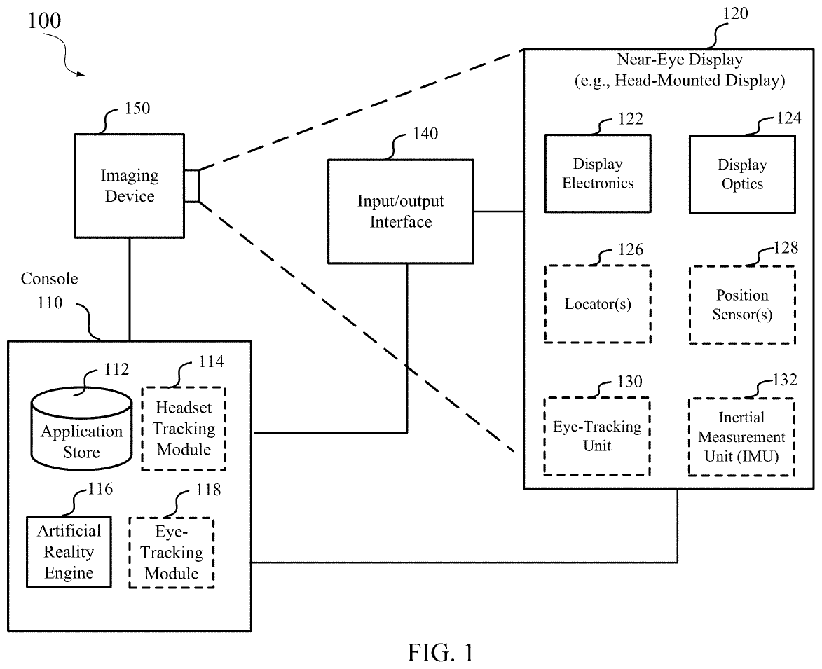

FIG. 1 is a simplified block diagram of an example of an artificial reality system environment 100 including a near-eye display 120 in accordance with certain embodiments. Artificial reality system environment 100 shown in FIG. 1 may include near-eye display 120, an optional external imaging device 150, and an optional input/output interface 140, each of which may be coupled to an optional console 110. While FIG. 1 shows an example of artificial reality system environment 100 including one near-eye display 120, one external imaging device 150, and one input/output interface 140, any number of these components may be included in artificial reality system environment 100, or any of the components may be omitted. For example, there may be multiple near-eye displays 120 monitored by one or more external imaging devices 150 in communication with console 110. In some configurations, artificial reality system environment 100 may not include external imaging device 150, optional input/output interface 140, and optional console 110. In alternative configurations, different or additional components may be included in artificial reality system environment 100.

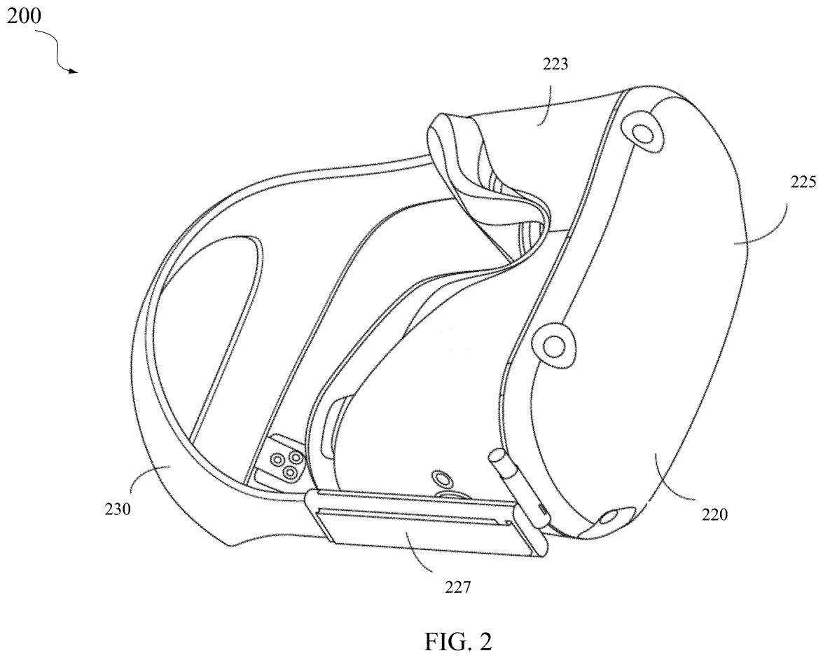

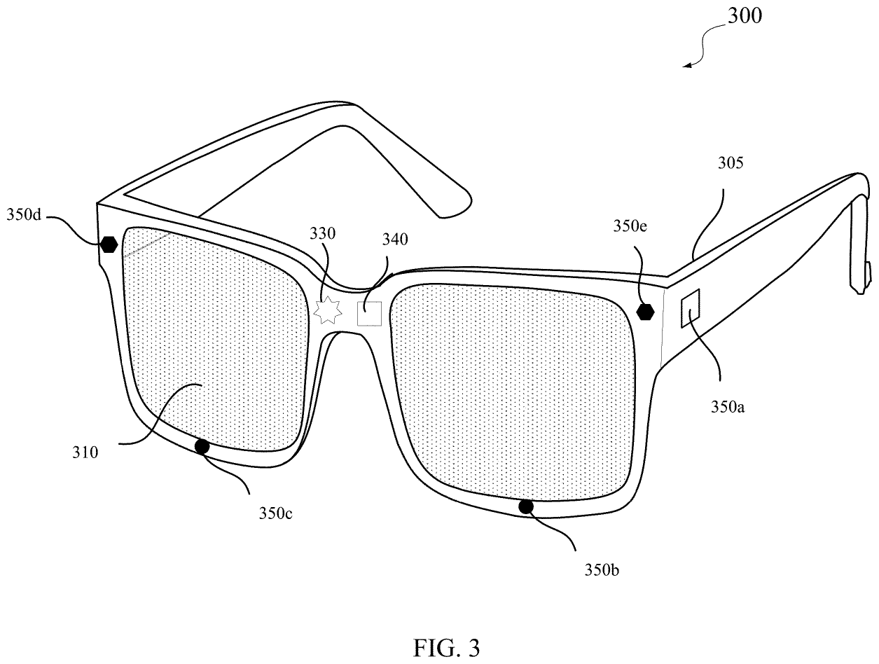

Near-eye display 120 may be a head-mounted display that presents content to a user. Examples of content presented by near-eye display 120 include one or more of images, videos, audio, or any combination thereof. In some embodiments, audio may be presented via an external device (e.g., speakers and/or headphones) that receives audio information from near-eye display 120, console 110, or both, and presents audio data based on the audio information. Near-eye display 120 may include one or more rigid bodies, which may be rigidly or non-rigidly coupled to each other. A rigid coupling between rigid bodies may cause the coupled rigid bodies to act as a single rigid entity. A non-rigid coupling between rigid bodies may allow the rigid bodies to move relative to each other. In various embodiments, near-eye display 120 may be implemented in any suitable form-factor, including a pair of glasses. Some embodiments of near-eye display 120 are further described below with respect to FIGS. 2 and 3. Additionally, in various embodiments, the functionality described herein may be used in a headset that combines images of an environment external to near-eye display 120 and artificial reality content (e.g., computer-generated images). Therefore, near-eye display 120 may augment images of a physical, real-world environment external to near-eye display 120 with generated content (e.g., images, video, sound, etc.) to present an augmented reality to a user.

In various embodiments, near-eye display 120 may include one or more of display electronics 122, display optics 124, and an eye-tracking unit 130. In some embodiments, near-eye display 120 may also include one or more locators 126, one or more position sensors 128, and an inertial measurement unit (IMU) 132. Near-eye display 120 may omit any of eye-tracking unit 130, locators 126, position sensors 128, and IMU 132, or include additional elements in various embodiments. Additionally, in some embodiments, near-eye display 120 may include elements combining the function of various elements described in conjunction with FIG. 1.

Display electronics 122 may display or facilitate the display of images to the user according to data received from, for example, console 110. In various embodiments, display electronics 122 may include one or more display panels, such as a liquid crystal display (LCD), an organic light emitting diode (OLED) display, an inorganic light emitting diode (ILED) display, a micro light emitting diode (LED) display, an active-matrix OLED display (AMOLED), a transparent OLED display (TOLED), or some other display. For example, in one implementation of near-eye display 120, display electronics 122 may include a front TOLED panel, a rear display panel, and an optical component (e.g., an attenuator, polarizer, or diffractive or spectral film) between the front and rear display panels. Display electronics 122 may include pixels to emit light of a predominant color such as red, green, blue, white, or yellow. In some implementations, display electronics 122 may display a three-dimensional (3D) image through stereoscopic effects produced by two-dimensional panels to create a subjective perception of image depth. For example, display electronics 122 may include a left display and a right display positioned in front of a user's left eye and right eye, respectively. The left and right displays may present copies of an image shifted horizontally relative to each other to create a stereoscopic effect (i.e., a perception of image depth by a user viewing the image).

In certain embodiments, display optics 124 may display image content optically (e.g., using optical waveguides and couplers) or magnify image light received from display electronics 122, correct optical errors associated with the image light, and present the corrected image light to a user of near-eye display 120. In various embodiments, display optics 124 may include one or more optical elements, such as, for example, a substrate, optical waveguides, an aperture, a Fresnel lens, a convex lens, a concave lens, a filter, input/output couplers, or any other suitable optical elements that may affect image light emitted from display electronics 122. Display optics 124 may include a combination of different optical elements as well as mechanical couplings to maintain relative spacing and orientation of the optical elements in the combination. One or more optical elements in display optics 124 may have an optical coating, such as an anti-reflective coating, a reflective coating, a filtering coating, or a combination of different optical coatings.

Magnification of the image light by display optics 124 may allow display electronics 122 to be physically smaller, weigh less, and consume less power than larger displays. Additionally, magnification may increase a field of view of the displayed content. The amount of magnification of image light by display optics 124 may be changed by adjusting, adding, or removing optical elements from display optics 124. In some embodiments, display optics 124 may project displayed images to one or more image planes that may be further away from the user's eyes than near-eye display 120.

Display optics 124 may also be designed to correct one or more types of optical errors, such as two-dimensional optical errors, three-dimensional optical errors, or any combination thereof. Two-dimensional errors may include optical aberrations that occur in two dimensions. Example types of two-dimensional errors may include barrel distortion, pincushion distortion, longitudinal chromatic aberration, and transverse chromatic aberration. Three-dimensional errors may include optical errors that occur in three dimensions. Example types of three-dimensional errors may include spherical aberration, comatic aberration, field curvature, and astigmatism.

Locators 126 may be objects located in specific positions on near-eye display 120 relative to one another and relative to a reference point on near-eye display 120. In some implementations, console 110 may identify locators 126 in images captured by external imaging device 150 to determine the artificial reality headset's position, orientation, or both. A locator 126 may be an LED, a corner cube reflector, a reflective marker, a type of light source that contrasts with an environment in which near-eye display 120 operates, or any combination thereof. In embodiments where locators 126 are active components (e.g., LEDs or other types of light emitting devices), locators 126 may emit light in the visible band (e.g., about 380 nm to 750 nm), in the infrared (IR) band (e.g., about 750 nm to 1 mm), in the ultraviolet band (e.g., about nm to about 380 nm), in another portion of the electromagnetic spectrum, or in any combination of portions of the electromagnetic spectrum.

External imaging device 150 may include one or more cameras, one or more video cameras, any other device capable of capturing images including one or more of locators 126, or any combination thereof. Additionally, external imaging device 150 may include one or more filters (e.g., to increase signal to noise ratio). External imaging device 150 may be configured to detect light emitted or reflected from locators 126 in a field of view of external imaging device 150. In embodiments where locators 126 include passive elements (e.g., retroreflectors), external imaging device 150 may include a light source that illuminates some or all of locators 126, which may retro-reflect the light to the light source in external imaging device 150. Slow calibration data may be communicated from external imaging device 150 to console 110, and external imaging device 150 may receive one or more calibration parameters from console 110 to adjust one or more imaging parameters (e.g., focal length, focus, frame rate, sensor temperature, shutter speed, aperture, etc.).

Position sensors 128 may generate one or more measurement signals in response to motion of near-eye display 120. Examples of position sensors 128 may include accelerometers, gyroscopes, magnetometers, other motion-detecting or error-correcting sensors, or any combination thereof. For example, in some embodiments, position sensors 128 may include multiple accelerometers to measure translational motion (e.g., forward/back, up/down, or left/right) and multiple gyroscopes to measure rotational motion (e.g., pitch, yaw, or roll). In some embodiments, various position sensors may be oriented orthogonally to each other.

IWU 132 may be an electronic device that generates fast calibration data based on measurement signals received from one or more of position sensors 128. Position sensors 128 may be located external to IMU 132, internal to IMU 132, or any combination thereof. Based on the one or more measurement signals from one or more position sensors 128, IMU 132 may generate fast calibration data indicating an estimated position of near-eye display 120 relative to an initial position of near-eye display 120. For example, IMU 132 may integrate measurement signals received from accelerometers over time to estimate a velocity vector and integrate the velocity vector over time to determine an estimated position of a reference point on near-eye display 120. Alternatively, IWU 132 may provide the sampled measurement signals to console 110, which may determine the fast calibration data. While the reference point may generally be defined as a point in space, in various embodiments, the reference point may also be defined as a point within near-eye display 120 (e.g., a center of IMU 132).

Eye-tracking unit 130 may include one or more eye-tracking systems. Eye tracking may refer to determining an eye's position, including orientation and location of the eye, relative to near-eye display 120. An eye-tracking system may include an imaging system to image one or more eyes and may optionally include a light emitter, which may generate light that is directed to an eye such that light reflected by the eye may be captured by the imaging system. For example, eye-tracking unit 130 may include a non-coherent or coherent light source (e.g., a laser diode) emitting light in the visible spectrum or infrared spectrum, and a camera capturing the light reflected by the user's eye. As another example, eye-tracking unit 130 may capture reflected radio waves emitted by a miniature radar unit. Eye-tracking unit 130 may use low-power light emitters that emit light at frequencies and intensities that would not injure the eye or cause physical discomfort. Eye-tracking unit 130 may be arranged to increase contrast in images of an eye captured by eye-tracking unit 130 while reducing the overall power consumed by eye-tracking unit 130 (e.g., reducing power consumed by a light emitter and an imaging system included in eye-tracking unit 130). For example, in some implementations, eye-tracking unit 130 may consume less than 100 milliwatts of power.

Near-eye display 120 may use the orientation of the eye to, e.g., determine an inter-pupillary distance (IPD) of the user, determine gaze direction, introduce depth cues (e.g., blur image outside of the user's main line of sight), collect heuristics on the user interaction in the VR media (e.g., time spent on any particular subject, object, or frame as a function of exposed stimuli), some other functions that are based in part on the orientation of at least one of the user's eyes, or any combination thereof. Because the orientation may be determined for both eyes of the user, eye-tracking unit 130 may be able to determine where the user is looking. For example, determining a direction of a user's gaze may include determining a point of convergence based on the determined orientations of the user's left and right eyes. A point of convergence may be the point where the two foveal axes of the user's eyes intersect. The direction of the user's gaze may be the direction of a line passing through the point of convergence and the mid-point between the pupils of the user's eyes.

Input/output interface 140 may be a device that allows a user to send action requests to console 110. An action request may be a request to perform a particular action. For example, an action request may be to start or to end an application or to perform a particular action within the application. Input/output interface 140 may include one or more input devices. Example input devices may include a keyboard, a mouse, a game controller, a glove, a button, a touch screen, or any other suitable device for receiving action requests and communicating the received action requests to console 110. An action request received by the input/output interface 140 may be communicated to console 110, which may perform an action corresponding to the requested action. In some embodiments, input/output interface 140 may provide haptic feedback to the user in accordance with instructions received from console 110. For example, input/output interface 140 may provide haptic feedback when an action request is received, or when console 110 has performed a requested action and communicates instructions to input/output interface 140. In some embodiments, external imaging device 150 may be used to track input/output interface 140, such as tracking the location or position of a controller (which may include, for example, an IR light source) or a hand of the user to determine the motion of the user. In some embodiments, near-eye display 120 may include one or more imaging devices to track input/output interface 140, such as tracking the location or position of a controller or a hand of the user to determine the motion of the user.

Console 110 may provide content to near-eye display 120 for presentation to the user in accordance with information received from one or more of external imaging device 150, near-eye display 120, and input/output interface 140. In the example shown in FIG. 1, console 110 may include an application store 112, a headset tracking module 114, an artificial reality engine 116, and an eye-tracking module 118. Some embodiments of console 110 may include different or additional modules than those described in conjunction with FIG. 1. Functions further described below may be distributed among components of console 110 in a different manner than is described here.

In some embodiments, console 110 may include a processor and a non-transitory computer-readable storage medium storing instructions executable by the processor. The processor may include multiple processing units executing instructions in parallel. The non-transitory computer-readable storage medium may be any memory, such as a hard disk drive, a removable memory, or a solid-state drive (e.g., flash memory or dynamic random access memory (DRAM)). In various embodiments, the modules of console 110 described in conjunction with FIG. 1 may be encoded as instructions in the non-transitory computer-readable storage medium that, when executed by the processor, cause the processor to perform the functions further described below.

Application store 112 may store one or more applications for execution by console 110. An application may include a group of instructions that, when executed by a processor, generates content for presentation to the user. Content generated by an application may be in response to inputs received from the user via movement of the user's eyes or inputs received from the input/output interface 140. Examples of the applications may include gaming applications, conferencing applications, video playback application, or other suitable applications.

Headset tracking module 114 may track movements of near-eye display 120 using slow calibration information from external imaging device 150. For example, headset tracking module 114 may determine positions of a reference point of near-eye display 120 using observed locators from the slow calibration information and a model of near-eye display 120. Headset tracking module 114 may also determine positions of a reference point of near-eye display 120 using position information from the fast calibration information. Additionally, in some embodiments, headset tracking module 114 may use portions of the fast calibration information, the slow calibration information, or any combination thereof, to predict a future location of near-eye display 120. Headset tracking module 114 may provide the estimated or predicted future position of near-eye display 120 to artificial reality engine 116.

Artificial reality engine 116 may execute applications within artificial reality system environment 100 and receive position information of near-eye display 120, acceleration information of near-eye display 120, velocity information of near-eye display 120, predicted future positions of near-eye display 120, or any combination thereof from headset tracking module 114. Artificial reality engine 116 may also receive estimated eye position and orientation information from eye-tracking module 118. Based on the received information, artificial reality engine 116 may determine content to provide to near-eye display 120 for presentation to the user. For example, if the received information indicates that the user has looked to the left, artificial reality engine 116 may generate content for near-eye display 120 that mirrors the user's eye movement in a virtual environment. Additionally, artificial reality engine 116 may perform an action within an application executing on console 110 in response to an action request received from input/output interface 140, and provide feedback to the user indicating that the action has been performed. The feedback may be visual or audible feedback via near-eye display 120 or haptic feedback via input/output interface 140.

Eye-tracking module 118 may receive eye-tracking data from eye-tracking unit 130 and determine the position of the user's eye based on the eye tracking data. The position of the eye may include an eye's orientation, location, or both relative to near-eye display 120 or any element thereof. Because the eye's axes of rotation change as a function of the eye's location in its socket, determining the eye's location in its socket may allow eye-tracking module 118 to more accurately determine the eye's orientation.

FIG. 2 is a perspective view of an example of a near-eye display in the form of an HMD device 200 for implementing some of the examples disclosed herein. HMD device 200 may be a part of, e.g., a VR system, an AR system, an MR system, or any combination thereof. HMD device 200 may include a body 220 and a head strap 230. FIG. 2 shows a bottom side 223, a front side 225, and a left side 227 of body 220 in the perspective view. Head strap 230 may have an adjustable or extendible length. There may be a sufficient space between body 220 and head strap 230 of HMD device 200 for allowing a user to mount HMD device 200 onto the user's head. In various embodiments, HMD device 200 may include additional, fewer, or different components. For example, in some embodiments, HMD device 200 may include eyeglass temples and temple tips as shown in, for example, FIG. 3 below, rather than head strap 230.

HMD device 200 may present to a user media including virtual and/or augmented views of a physical, real-world environment with computer-generated elements. Examples of the media presented by HMD device 200 may include images (e.g., two-dimensional (2D) or three-dimensional (3D) images), videos (e.g., 2D or 3D videos), audio, or any combination thereof. The images and videos may be presented to each eye of the user by one or more display assemblies (not shown in FIG. 2) enclosed in body 220 of HMD device 200. In various embodiments, the one or more display assemblies may include a single electronic display panel or multiple electronic display panels (e.g., one display panel for each eye of the user). Examples of the electronic display panel(s) may include, for example, an LCD, an OLED display, an ILED display, a μLED display, an AMOLED, a TOLED, some other display, or any combination thereof. HMD device 200 may include two eye box regions.

In some implementations, HMD device 200 may include various sensors (not shown), such as depth sensors, motion sensors, position sensors, and eye tracking sensors. Some of these sensors may use a structured light pattern for sensing. In some implementations, HMD device 200 may include an input/output interface for communicating with a console. In some implementations, HMD device 200 may include a virtual reality engine (not shown) that can execute applications within HMD device 200 and receive depth information, position information, acceleration information, velocity information, predicted future positions, or any combination thereof of HMD device 200 from the various sensors. In some implementations, the information received by the virtual reality engine may be used for producing a signal (e.g., display instructions) to the one or more display assemblies. In some implementations, HMD device 200 may include locators (not shown, such as locators 126) located in fixed positions on body 220 relative to one another and relative to a reference point. Each of the locators may emit light that is detectable by an external imaging device.

FIG. 3 is a perspective view of an example of a near-eye display 300 in the form of a pair of glasses for implementing some of the examples disclosed herein. Near-eye display 300 may be a specific implementation of near-eye display 120 of FIG. 1, and may be configured to operate as a virtual reality display, an augmented reality display, and/or a mixed reality display. Near-eye display 300 may include a frame 305 and a display 310. Display 310 may be configured to present content to a user. In some embodiments, display 310 may include display electronics and/or display optics. For example, as described above with respect to near-eye display 120 of FIG. 1, display 310 may include an LCD display panel, an LED display panel, or an optical display panel (e.g., a waveguide display assembly).

Near-eye display 300 may further include various sensors 350a, 350b, 350c, 350d, and 350e on or within frame 305. In some embodiments, sensors 350a-350e may include one or more depth sensors, motion sensors, position sensors, inertial sensors, or ambient light sensors. In some embodiments, sensors 350a-350e may include one or more image sensors configured to generate image data representing different fields of views in different directions. In some embodiments, sensors 350a-350e may be used as input devices to control or influence the displayed content of near-eye display 300, and/or to provide an interactive VR/AR/MR experience to a user of near-eye display 300. In some embodiments, sensors 350a-350e may also be used for stereoscopic imaging.

In some embodiments, near-eye display 300 may further include one or more illuminators 330 to project light into the physical environment. The projected light may be associated with different frequency bands (e.g., visible light, infra-red light, ultra-violet light, etc.), and may serve various purposes. For example, illuminator(s) 330 may project light in a dark environment (or in an environment with low intensity of infra-red light, ultra-violet light, etc.) to assist sensors 350a-350e in capturing images of different objects within the dark environment. In some embodiments, illuminator(s) 330 may be used to project certain light patterns onto the objects within the environment. In some embodiments, illuminator(s) 330 may be used as locators, such as locators 126 described above with respect to FIG. 1.

In some embodiments, near-eye display 300 may also include a high-resolution camera 340. Camera 340 may capture images of the physical environment in the field of view. The captured images may be processed, for example, by a virtual reality engine (e.g., artificial reality engine 116 of FIG. 1) to add virtual objects to the captured images or modify physical objects in the captured images, and the processed images may be displayed to the user by display 310 for AR or MR applications.

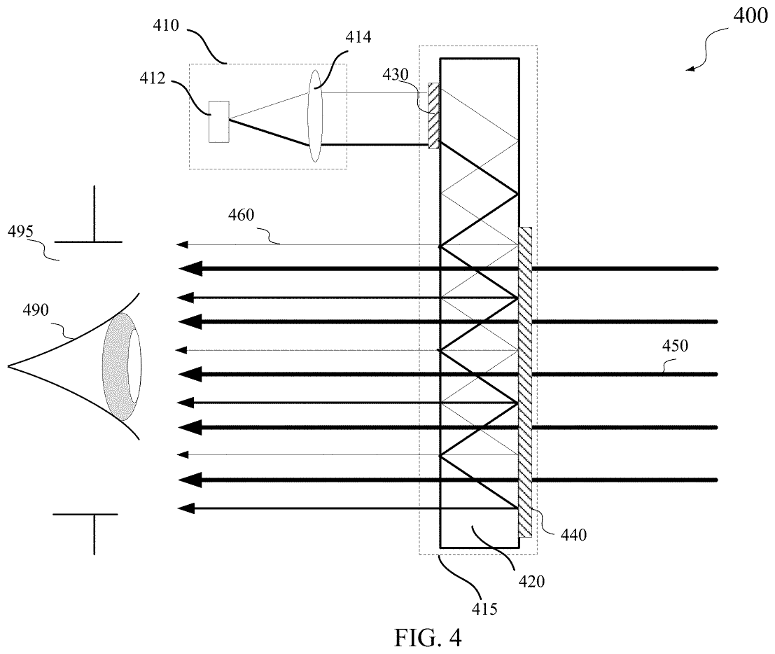

FIG. 4 illustrates an example of an optical see-through augmented reality system 400 including a waveguide display according to certain embodiments. Augmented reality system 400 may include a projector 410 and a combiner 415. Projector 410 may include a light source or image source 412 and projector optics 414. In some embodiments, light source or image source 412 may include one or more micro-LED devices described above. In some embodiments, image source 412 may include a plurality of pixels that displays virtual objects, such as an LCD display panel or an LED display panel. In some embodiments, image source 412 may include a light source that generates coherent or partially coherent light. For example, image source 412 may include a laser diode, a vertical cavity surface emitting laser, an LED, and/or a micro-LED described above. In some embodiments, image source 412 may include a plurality of light sources (e.g., an array of micro-LEDs described above), each emitting a monochromatic image light corresponding to a primary color (e.g., red, green, or blue). In some embodiments, image source 412 may include three two-dimensional arrays of micro-LEDs, where each two-dimensional array of micro-LEDs may include micro-LEDs configured to emit light of a primary color (e.g., red, green, or blue). In some embodiments, image source 412 may include an optical pattern generator, such as a spatial light modulator. Projector optics 414 may include one or more optical components that can condition the light from image source 412, such as expanding, collimating, scanning, or projecting light from image source 412 to combiner 415. The one or more optical components may include, for example, one or more lenses, liquid lenses, mirrors, apertures, and/or gratings. For example, in some embodiments, image source 412 may include one or more one-dimensional arrays or elongated two-dimensional arrays of micro-LEDs, and projector optics 414 may include one or more one-dimensional scanners (e.g., micro-mirrors or prisms) configured to scan the one-dimensional arrays or elongated two-dimensional arrays of micro-LEDs to generate image frames. In some embodiments, projector optics 414 may include a liquid lens (e.g., a liquid crystal lens) with a plurality of electrodes that allows scanning of the light from image source 412.

Combiner 415 may include an input coupler 430 for coupling light from projector 410 into a substrate 420 of combiner 415. Combiner 415 may transmit at least 50% of light in a first wavelength range and reflect at least 25% of light in a second wavelength range. For example, the first wavelength range may be visible light from about 400 nm to about 650 nm, and the second wavelength range may be in the infrared band, for example, from about 800 nm to about 1000 nm. Input coupler 430 may include a volume holographic grating, a diffractive optical element (DOE) (e.g., a surface-relief grating), a slanted surface of substrate 420, or a refractive coupler (e.g., a wedge or a prism). For example, input coupler 430 may include a reflective volume Bragg grating or a transmissive volume Bragg grating. Input coupler 430 may have a coupling efficiency of greater than 30%, 50%, 75%, 90%, or higher for visible light. Light coupled into substrate 420 may propagate within substrate 420 through, for example, total internal reflection (TIR). Substrate 420 may be in the form of a lens of a pair of eyeglasses. Substrate 420 may have a flat or a curved surface, and may include one or more types of dielectric materials, such as glass, quartz, plastic, polymer, poly(methyl methacrylate) (PMMA), crystal, or ceramic. A thickness of the substrate may range from, for example, less than about 1 mm to about 10 mm or more. Substrate 420 may be transparent to visible light.

Substrate 420 may include or may be coupled to a plurality of output couplers 440, each configured to extract at least a portion of the light guided by and propagating within substrate 420 from substrate 420, and direct extracted light 460 to an eyebox 495 where an eye 490 of the user of augmented reality system 400 may be located when augmented reality system 400 is in use. The plurality of output couplers 440 may replicate the exit pupil to increase the size of eyebox 495 such that the displayed image is visible in a larger area. As input coupler 430, output couplers 440 may include grating couplers (e.g., volume holographic gratings or surface-relief gratings), other diffraction optical elements (DOEs), prisms, etc. For example, output couplers 440 may include reflective volume Bragg gratings or transmissive volume Bragg gratings. Output couplers 440 may have different coupling (e.g., diffraction) efficiencies at different locations. Substrate 420 may also allow light 450 from the environment in front of combiner 415 to pass through with little or no loss. Output couplers 440 may also allow light 450 to pass through with little loss. For example, in some implementations, output couplers 440 may have a very low diffraction efficiency for light 450 such that light 450 may be refracted or otherwise pass through output couplers 440 with little loss, and thus may have a higher intensity than extracted light 460. In some implementations, output couplers 440 may have a high diffraction efficiency for light 450 and may diffract light 450 in certain desired directions (i.e., diffraction angles) with little loss. As a result, the user may be able to view combined images of the environment in front of combiner 415 and images of virtual objects projected by projector 410.

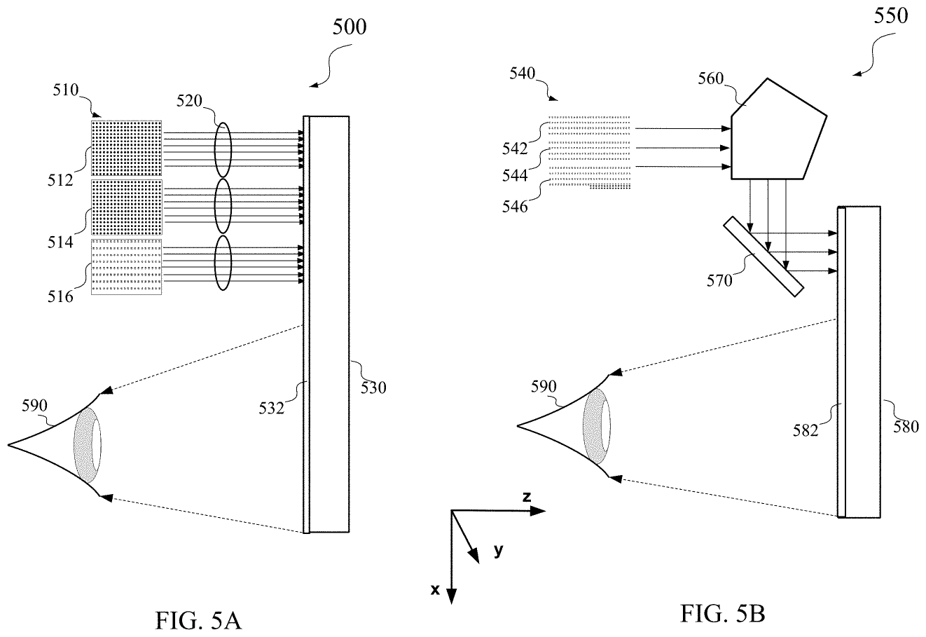

FIG. 5A illustrates an example of a near-eye display (NED) device 500 including a waveguide display 530 according to certain embodiments. NED device 500 may be an example of near-eye display 120, augmented reality system 400, or another type of display device. NED device 500 may include a light source 510, projection optics 520, and waveguide display 530. Light source 510 may include multiple panels of light emitters for different colors, such as a panel of red light emitters 512, a panel of green light emitters 514, and a panel of blue light emitters 516. The red light emitters 512 are organized into an array; the green light emitters 514 are organized into an array; and the blue light emitters 516 are organized into an array. The dimensions and pitches of light emitters in light source 510 may be small. For example, each light emitter may have a diameter less than 2 μm (e.g., about 1.2 μm) and the pitch may be less than 2 μm (e.g., about 1.5 μm). As such, the number of light emitters in each red light emitters 512, green light emitters 514, and blue light emitters 516 can be equal to or greater than the number of pixels in a display image, such as 960×720, 1280×720, 1440×1080, 1920×1080, 2160×1080, or 2560×1080 pixels. Thus, a display image may be generated simultaneously by light source 510. A scanning element may not be used in NED device 500.

Before reaching waveguide display 530, the light emitted by light source 510 may be conditioned by projection optics 520, which may include a lens array. Projection optics 520 may collimate or focus the light emitted by light source 510 to waveguide display 530, which may include a coupler 532 for coupling the light emitted by light source 510 into waveguide display 530. The light coupled into waveguide display 530 may propagate within waveguide display 530 through, for example, total internal reflection as described above with respect to FIG. 4. Coupler 532 may also couple portions of the light propagating within waveguide display 530 out of waveguide display 530 and towards user's eye 590.

FIG. 5B illustrates an example of a near-eye display (NED) device 550 including a waveguide display 580 according to certain embodiments. In some embodiments, NED device 550 may use a scanning mirror 570 to project light from a light source 540 to an image field where a user's eye 590 may be located. NED device 550 may be an example of near-eye display 120, augmented reality system 400, or another type of display device. Light source 540 may include one or more rows or one or more columns of light emitters of different colors, such as multiple rows of red light emitters 542, multiple rows of green light emitters 544, and multiple rows of blue light emitters 546. For example, red light emitters 542, green light emitters 544, and blue light emitters 546 may each include N rows, each row including, for example, 2560 light emitters (pixels). The red light emitters 542 are organized into an array; the green light emitters 544 are organized into an array; and the blue light emitters 546 are organized into an array. In some embodiments, light source 540 may include a single line of light emitters for each color. In some embodiments, light source 540 may include multiple columns of light emitters for each of red, green, and blue colors, where each column may include, for example, 1080 light emitters. In some embodiments, the dimensions and/or pitches of the light emitters in light source 540 may be relatively large (e.g., about 3-5 μm) and thus light source 540 may not include sufficient light emitters for simultaneously generating a full display image. For example, the number of light emitters for a single color may be fewer than the number of pixels (e.g., 2560×1080 pixels) in a display image. The light emitted by light source 540 may be a set of collimated or diverging beams of light.

Before reaching scanning mirror 570, the light emitted by light source 540 may be conditioned by various optical devices, such as collimating lenses or a freeform optical element 560. Freeform optical element 560 may include, for example, a multi-facet prism or another light folding element that may direct the light emitted by light source 540 towards scanning mirror 570, such as changing the propagation direction of the light emitted by light source 540 by, for example, about 900 or larger. In some embodiments, freeform optical element 560 may be rotatable to scan the light. Scanning mirror 570 and/or freeform optical element 560 may reflect and project the light emitted by light source 540 to waveguide display 580, which may include a coupler 582 for coupling the light emitted by light source 540 into waveguide display 580. The light coupled into waveguide display 580 may propagate within waveguide display 580 through, for example, total internal reflection as described above with respect to FIG. 4. Coupler 582 may also couple portions of the light propagating within waveguide display 580 out of waveguide display 580 and towards user's eye 590.

Scanning mirror 570 may include a microelectromechanical system (MEMS) mirror or any other suitable mirrors. Scanning mirror 570 may rotate to scan in one or two dimensions. As scanning mirror 570 rotates, the light emitted by light source 540 may be directed to a different area of waveguide display 580 such that a full display image may be projected onto waveguide display 580 and directed to user's eye 590 by waveguide display 580 in each scanning cycle. For example, in embodiments where light source 540 includes light emitters for all pixels in one or more rows or columns, scanning mirror 570 may be rotated in the column or row direction (e.g., x or y direction) to scan an image. In embodiments where light source 540 includes light emitters for some but not all pixels in one or more rows or columns, scanning mirror 570 may be rotated in both the row and column directions (e.g., both x and y directions) to project a display image (e.g., using a raster-type scanning pattern).

NED device 550 may operate in predefined display periods. A display period (e.g., display cycle) may refer to a duration of time in which a full image is scanned or projected. For example, a display period may be a reciprocal of the desired frame rate. In NED device 550 that includes scanning mirror 570, the display period may also be referred to as a scanning period or scanning cycle. The light generation by light source 540 may be synchronized with the rotation of scanning mirror 570. For example, each scanning cycle may include multiple scanning steps, where light source 540 may generate a different light pattern in each respective scanning step.

In each scanning cycle, as scanning mirror 570 rotates, a display image may be projected onto waveguide display 580 and user's eye 590. The actual color value and light intensity (e.g., brightness) of a given pixel location of the display image may be an average of the light beams of the three colors (e.g., red, green, and blue) illuminating the pixel location during the scanning period. After completing a scanning period, scanning mirror 570 may revert back to the initial position to project light for the first few rows of the next display image or may rotate in a reverse direction or scan pattern to project light for the next display image, where a new set of driving signals may be fed to light source 540. The same process may be repeated as scanning mirror 570 rotates in each scanning cycle. As such, different images may be projected to user's eye 590 in different scanning cycles.

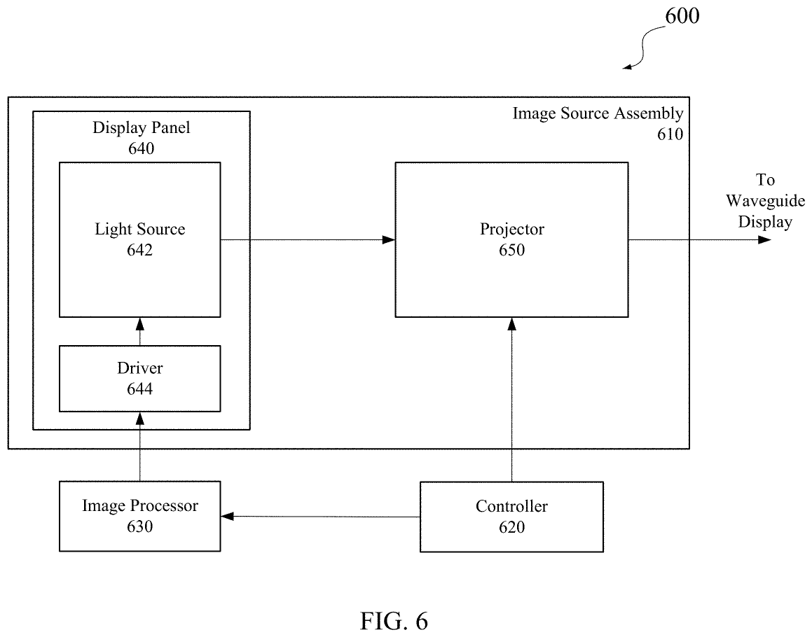

FIG. 6 illustrates an example of an image source assembly 610 in a near-eye display system 600 according to certain embodiments. Image source assembly 610 may include, for example, a display panel 640 that may generate display images to be projected to the user's eyes, and a projector 650 that may project the display images generated by display panel 640 to a waveguide display as described above with respect to FIGS. 4-5B. Display panel 640 may include a light source 642 and a driver circuit 644 for light source 642. Light source 642 may include, for example, light source 510 or 540. Projector 650 may include, for example, freeform optical element 560, scanning mirror 570, and/or projection optics 520 described above. Near-eye display system 600 may also include a controller 620 that synchronously controls light source 642 and projector 650 (e.g., scanning mirror 570). Image source assembly 610 may generate and output an image light to a waveguide display (not shown in FIG. 6), such as waveguide display 530 or 580. As described above, the waveguide display may receive the image light at one or more input-coupling elements, and guide the received image light to one or more output-coupling elements. The input and output coupling elements may include, for example, a diffraction grating, a holographic grating, a prism, or any combination thereof. The input-coupling element may be chosen such that total internal reflection occurs with the waveguide display. The output-coupling element may couple portions of the total internally reflected image light out of the waveguide display.

As described above, light source 642 may include a plurality of light emitters arranged in an array or a matrix. Each light emitter may emit monochromatic light, such as red light, blue light, green light, infra-red light, and the like. While RGB colors are often discussed in this disclosure, embodiments described herein are not limited to using red, green, and blue as primary colors. Other colors can also be used as the primary colors of near-eye display system 600. In some embodiments, a display panel in accordance with an embodiment may use more than three primary colors. Each pixel in light source 642 may include three subpixels that include a red micro-LED, a green micro-LED, and a blue micro-LED. A semiconductor LED generally includes an active light emitting layer within multiple layers of semiconductor materials. The multiple layers of semiconductor materials may include different compound materials or a same base material with different dopants and/or different doping densities. For example, the multiple layers of semiconductor materials may include an n-type material layer, an active region that may include hetero-structures (e.g., one or more quantum wells), and a p-type material layer. The multiple layers of semiconductor materials may be grown on a surface of a substrate having a certain orientation. In some embodiments, to increase light extraction efficiency, a mesa that includes at least some of the layers of semiconductor materials may be formed.

Controller 620 may control the image rendering operations of image source assembly 610, such as the operations of light source 642 and/or projector 650. For example, controller 620 may determine instructions for image source assembly 610 to render one or more display images. The instructions may include display instructions and scanning instructions. In some embodiments, the display instructions may include an image file (e.g., a bitmap file). The display instructions may be received from, for example, a console, such as console 110 described above with respect to FIG. 1. The scanning instructions may be used by image source assembly 610 to generate image light. The scanning instructions may specify, for example, a type of a source of image light (e.g., monochromatic or polychromatic), a scanning rate, an orientation of a scanning apparatus, one or more illumination parameters, or any combination thereof. Controller 620 may include a combination of hardware, software, and/or firmware not shown here so as not to obscure other aspects of the present disclosure.

In some embodiments, controller 620 may be a graphics processing unit (GPU) of a display device. In other embodiments, controller 620 may be other kinds of processors. The operations performed by controller 620 may include taking content for display and dividing the content into discrete sections. Controller 620 may provide to light source 642 scanning instructions that include an address corresponding to an individual source element of light source 642 and/or an electrical bias applied to the individual source element. Controller 620 may instruct light source 642 to sequentially present the discrete sections using light emitters corresponding to one or more rows of pixels in an image ultimately displayed to the user. Controller 620 may also instruct projector 650 to perform different adjustments of the light. For example, controller 620 may control projector 650 to scan the discrete sections to different areas of a coupling element of the waveguide display (e.g., waveguide display 580) as described above with respect to FIG. 5B. As such, at the exit pupil of the waveguide display, each discrete portion is presented in a different respective location. While each discrete section is presented at a different respective time, the presentation and scanning of the discrete sections occur fast enough such that a user's eye may integrate the different sections into a single image or series of images.

Image processor 630 may be a general-purpose processor and/or one or more application-specific circuits that are dedicated to performing the features described herein. In one embodiment, a general-purpose processor may be coupled to a memory to execute software instructions that cause the processor to perform certain processes described herein. In another embodiment, image processor 630 may be one or more circuits that are dedicated to performing certain features. While image processor 630 in FIG. 6 is shown as a stand-alone unit that is separate from controller 620 and driver circuit 644, image processor 630 may be a sub-unit of controller 620 or driver circuit 644 in other embodiments. In other words, in those embodiments, controller 620 or driver circuit 644 may perform various image processing functions of image processor 630. Image processor 630 may also be referred to as an image processing circuit.

In the example shown in FIG. 6, light source 642 may be driven by driver circuit 644, based on data or instructions (e.g., display and scanning instructions) sent from controller 620 or image processor 630. In one embodiment, driver circuit 644 may include a circuit panel that connects to and mechanically holds various light emitters of light source 642. Light source 642 may emit light in accordance with one or more illumination parameters that are set by the controller 620 and potentially adjusted by image processor 630 and driver circuit 644. An illumination parameter may be used by light source 642 to generate light. An illumination parameter may include, for example, source wavelength, pulse rate, pulse amplitude, beam type (continuous or pulsed), other parameter(s) that may affect the emitted light, or any combination thereof. In some embodiments, the source light generated by light source 642 may include multiple beams of red light, green light, and blue light, or any combination thereof.

Projector 650 may perform a set of optical functions, such as focusing, combining, conditioning, or scanning the image light generated by light source 642. In some embodiments, projector 650 may include a combining assembly, a light conditioning assembly, or a scanning mirror assembly. Projector 650 may include one or more optical components that optically adjust and potentially re-direct the light from light source 642. One example of the adjustment of light may include conditioning the light, such as expanding, collimating, correcting for one or more optical errors (e.g., field curvature, chromatic aberration, etc.), some other adjustments of the light, or any combination thereof. The optical components of projector 650 may include, for example, lenses, mirrors, apertures, gratings, or any combination thereof.

Projector 650 may redirect image light via its one or more reflective and/or refractive portions so that the image light is projected at certain orientations toward the waveguide display. The location where the image light is redirected toward the waveguide display may depend on specific orientations of the one or more reflective and/or refractive portions. In some embodiments, projector 650 includes a single scanning mirror that scans in at least two dimensions. In other embodiments, projector 650 may include a plurality of scanning mirrors that each scan in directions orthogonal to each other. Projector 650 may perform a raster scan (horizontally or vertically), a bi-resonant scan, or any combination thereof. In some embodiments, projector 650 may perform a controlled vibration along the horizontal and/or vertical directions with a specific frequency of oscillation to scan along two dimensions and generate a two-dimensional projected image of the media presented to user's eyes. In other embodiments, projector 650 may include a lens or prism that may serve similar or the same function as one or more scanning mirrors. In some embodiments, image source assembly 610 may not include a projector, where the light emitted by light source 642 may be directly incident on the waveguide display.

In semiconductor LEDs, photons are usually generated at a certain internal quantum efficiency through the recombination of electrons and holes within an active region (e.g., one or more semiconductor layers), where the internal quantum efficiency is the proportion of the radiative electron-hole recombination in the active region that emits photons. The generated light may then be extracted from the LEDs in a particular direction or within a particular solid angle. The ratio between the number of emitted photons extracted from an LED and the number of electrons passing through the LED is referred to as the external quantum efficiency, which describes how efficiently the LED converts injected electrons to photons that are extracted from the device.

The external quantum efficiency may be proportional to the injection efficiency, the internal quantum efficiency, and the extraction efficiency. The injection efficiency refers to the proportion of electrons passing through the device that are injected into the active region. The extraction efficiency is the proportion of photons generated in the active region that escape from the device. For LEDs, and in particular, micro-LEDs with reduced physical dimensions, improving the internal and external quantum efficiency and/or controlling the emission spectrum may be challenging. In some embodiments, to increase the light extraction efficiency, a mesa that includes at least some of the layers of semiconductor materials may be formed.

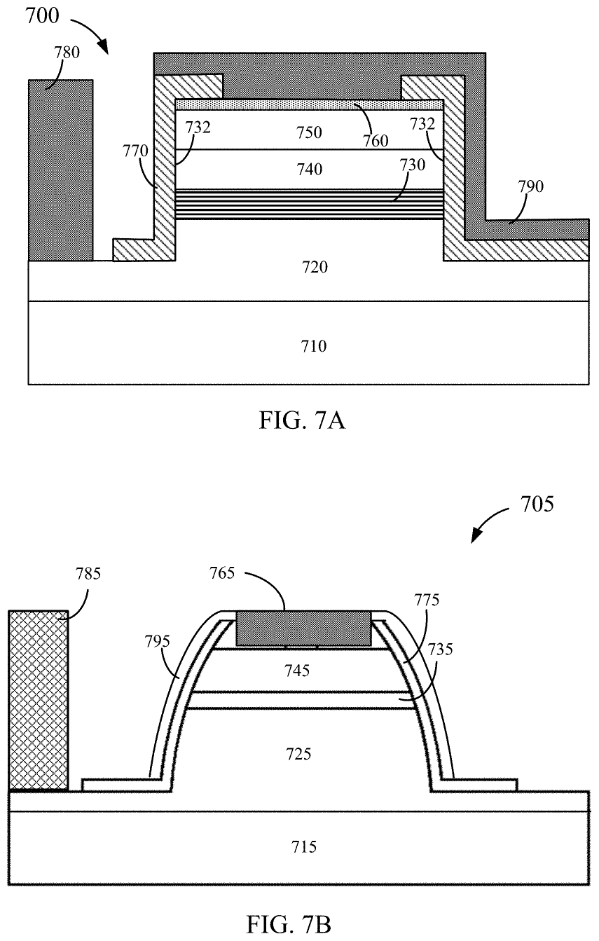

FIG. 7A illustrates an example of an LED 700 having a vertical mesa structure. LED 700 may be a light emitter in light source 510, 540, or 642. LED 700 may be a micro-LED made of inorganic materials, such as multiple layers of semiconductor materials. The layered semiconductor light emitting device may include multiple layers of III-V semiconductor materials. A III-V semiconductor material may include one or more Group III elements, such as aluminum (Al), gallium (Ga), or indium (In), in combination with a Group V element, such as nitrogen (N), phosphorus (P), arsenic (As), or antimony (Sb). When the Group V element of the III-V semiconductor material includes nitrogen, the III-V semiconductor material is referred to as a III-nitride material. The layered semiconductor light emitting device may be manufactured by growing multiple epitaxial layers on a substrate using techniques such as vapor-phase epitaxy (VPE), liquid-phase epitaxy (LPE), molecular beam epitaxy (MBE), or metalorganic chemical vapor deposition (MOCVD). For example, the layers of the semiconductor materials may be grown layer-by-layer on a substrate with a certain crystal lattice orientation (e.g., polar, nonpolar, or semi-polar orientation), such as a GaN, GaAs, or GaP substrate, or a substrate including, but not limited to, sapphire, silicon carbide, silicon, zinc oxide, boron nitride, lithium aluminate, lithium niobate, germanium, aluminum nitride, lithium gallate, partially substituted spinels, or quaternary tetragonal oxides sharing the beta-LiAlO₂ structure, where the substrate may be cut in a specific direction to expose a specific plane as the growth surface.

In the example shown in FIG. 7A, LED 700 may include a substrate 710, which may include, for example, a sapphire substrate or a GaN substrate. A semiconductor layer 720 may be grown on substrate 710. Semiconductor layer 720 may include a III-V material, such as GaN, and may be p-doped (e.g., with Mg, Ca, Zn, or Be) or n-doped (e.g., with Si or Ge). One or more active layers 730 may be grown on semiconductor layer 720 to form an active region. Active layer 730 may include III-V materials, such as one or more InGaN layers, one or more AlInGaP layers, and/or one or more GaN layers, which may form one or more heterostructures, such as one or more quantum wells or MQWs. A semiconductor layer 740 may be grown on active layer 730. Semiconductor layer 740 may include a III-V material, such as GaN, and may be p-doped (e.g., with Mg, Ca, Zn, or Be) or n-doped (e.g., with Si or Ge). One of semiconductor layer 720 and semiconductor layer 740 may be a p-type layer and the other one may be an n-type layer. Semiconductor layer 720 and semiconductor layer 740 sandwich active layer 730 to form the light emitting region. For example, LED 700 may include a layer of InGaN situated between a layer of p-type GaN doped with magnesium and a layer of n-type GaN doped with silicon or oxygen. In some embodiments, LED 700 may include a layer of AlInGaP situated between a layer of p-type AlInGaP doped with zinc or magnesium and a layer of n-type AlInGaP doped with selenium, silicon, or tellurium.

In some embodiments, an electron-blocking layer (EBL) (not shown in FIG. 7A) may be grown to form a layer between active layer 730 and at least one of semiconductor layer 720 or semiconductor layer 740. The EBL may reduce the electron leakage current and improve the efficiency of the LED. In some embodiments, a heavily-doped semiconductor layer 750, such as a P⁺ or P⁺⁺ semiconductor layer, may be formed on semiconductor layer 740 and act as a contact layer for forming an ohmic contact and reducing the contact impedance of the device. In some embodiments, a conductive layer 760 may be formed on heavily-doped semiconductor layer 750. Conductive layer 760 may include, for example, an indium tin oxide (ITO) or Al/Ni/Au film. In one example, conductive layer 760 may include a transparent ITO layer.

To make contact with semiconductor layer 720 (e.g., an n-GaN layer) and to more efficiently extract light emitted by active layer 730 from LED 700, the semiconductor material layers (including heavily-doped semiconductor layer 750, semiconductor layer 740, active layer 730, and semiconductor layer 720) may be etched to expose semiconductor layer 720 and to form a mesa structure that includes layers 720-760. The mesa structure may confine the carriers within the device. Etching the mesa structure may lead to the formation of mesa sidewalls 732 that may be orthogonal to the growth planes. A passivation layer 770 may be formed on sidewalls 732 of the mesa structure. Passivation layer 770 may include an oxide layer, such as a SiO₂ layer, and may act as a reflector to reflect emitted light out of LED 700. A contact layer 780, which may include a metal layer, such as Al, Au, Ni, Ti, or any combination thereof, may be formed on semiconductor layer 720 and may act as an electrode of LED 700. In addition, another contact layer 790, such as an Al/Ni/Au metal layer, may be formed on conductive layer 760 and may act as another electrode of LED 700.

When a voltage signal is applied to contact layers 780 and 790, electrons and holes may recombine in active layer 730, where the recombination of electrons and holes may cause photon emission. The wavelength and energy of the emitted photons may depend on the energy bandgap between the valence band and the conduction band in active layer 730. For example, InGaN active layers may emit green or blue light, AlGaN active layers may emit blue to ultraviolet light, while AlInGaP active layers may emit red, orange, yellow, or green light. The emitted photons may be reflected by passivation layer 770 and may exit LED 700 from the top (e.g., conductive layer 760 and contact layer 790) or bottom (e.g., substrate 710).

In some embodiments, LED 700 may include one or more other components, such as a lens, on the light emission surface, such as substrate 710, to focus or collimate the emitted light or couple the emitted light into a waveguide. In some embodiments, an LED may include a mesa of another shape, such as planar, conical, semi-parabolic, or parabolic, and a base area of the mesa may be circular, rectangular, hexagonal, or triangular. For example, the LED may include a mesa of a curved shape (e.g., paraboloid shape) and/or a non-curved shape (e.g., conic shape). The mesa may be truncated or non-truncated.

FIG. 7B is a cross-sectional view of an example of an LED 705 having a parabolic mesa structure. Similar to LED 700, LED 705 may include multiple layers of semiconductor materials, such as multiple layers of III-V semiconductor materials. The semiconductor material layers may be epitaxially grown on a substrate 715, such as a GaN substrate or a sapphire substrate. For example, a semiconductor layer 725 may be grown on substrate 715. Semiconductor layer 725 may include a III-V material, such as GaN, and may be p-doped (e.g., with Mg, Ca, Zn, or Be) or n-doped (e.g., with Si or Ge). One or more active layer 735 may be grown on semiconductor layer 725. Active layer 735 may include III-V materials, such as one or more InGaN layers, one or more AlInGaP layers, and/or one or more GaN layers, which may form one or more heterostructures, such as one or more quantum wells. A semiconductor layer 745 may be grown on active layer 735. Semiconductor layer 745 may include a III-V material, such as GaN, and may be p-doped (e.g., with Mg, Ca, Zn, or Be) or n-doped (e.g., with Si or Ge). One of semiconductor layer 725 and semiconductor layer 745 may be a p-type layer and the other one may be an n-type layer.

To make contact with semiconductor layer 725 (e.g., an n-type GaN layer) and to more efficiently extract light emitted by active layer 735 from LED 705, the semiconductor layers may be etched to expose semiconductor layer 725 and to form a mesa structure that includes layers 725-745. The mesa structure may confine carriers within the injection area of the device. Etching the mesa structure may lead to the formation of mesa side walls (also referred to herein as facets) that may be non-parallel with, or in some cases, orthogonal, to the growth planes associated with crystalline growth of layers 725-745.

As shown in FIG. 7B, LED 705 may have a mesa structure that includes a flat top. A dielectric layer 775 (e.g., SiO₂ or SiN_{X}) may be formed on the facets of the mesa structure. In some embodiments, dielectric layer 775 may include multiple layers of dielectric materials. In some embodiments, a metal layer 795 may be formed on dielectric layer 775. Metal layer 795 may include one or more metal or metal alloy materials, such as aluminum (Al), silver (Ag), gold (Au), platinum (Pt), titanium (Ti), copper (Cu), or any combination thereof. Dielectric layer 775 and metal layer 795 may form a mesa reflector that can reflect light emitted by active layer 735 toward substrate 715. In some embodiments, the mesa reflector may be parabolic-shaped to act as a parabolic reflector that may at least partially collimate the emitted light.

Electrical contact 765 and electrical contact 785 may be formed on semiconductor layer 745 and semiconductor layer 725, respectively, to act as electrodes. Electrical contact 765 and electrical contact 785 may each include a conductive material, such as Al, Au, Pt, Ag, Ni, Ti, Cu, or any combination thereof (e.g., Ag/Pt/Au or Al/Ni/Au), and may act as the electrodes of LED 705. In the example shown in FIG. 7B, electrical contact 785 may be an n-contact, and electrical contact 765 may be a p-contact. Electrical contact 765 and semiconductor layer 745 (e.g., a p-type semiconductor layer) may form a back reflector for reflecting light emitted by active layer 735 back toward substrate 715. In some embodiments, electrical contact 765 and metal layer 795 include same material(s) and can be formed using the same processes. In some embodiments, an additional conductive layer (not shown) may be included as an intermediate conductive layer between the electrical contacts 765 and 785 and the semiconductor layers.

When a voltage signal is applied across contacts 765 and 785, electrons and holes may recombine in active layer 735. The recombination of electrons and holes may cause photon emission, thus producing light. The wavelength and energy of the emitted photons may depend on the energy bandgap between the valence band and the conduction band in active layer 735. For example, InGaN active layers may emit green or blue light, while AlInGaP active layers may emit red, orange, yellow, or green light. The emitted photons may propagate in many different directions, and may be reflected by the mesa reflector and/or the back reflector and may exit LED 705, for example, from the bottom side (e.g., substrate 715) shown in FIG. 7B. One or more other secondary optical components, such as a lens or a grating, may be formed on the light emission surface, such as substrate 715, to focus or collimate the emitted light and/or couple the emitted light into a waveguide.

The overall efficiency of a waveguide-based display system may be the product of the efficiency of individual components in the display system and may also depend on how the components are coupled together. In a simplified example, the overall efficiency ηₜₒₜ of a waveguide-based display system may be determined as ηₜₒₜ=η_{EQE}×ηᵢₙ×ηₒᵤₜ, where η_{EQE} is the external quantum efficiency of a micro-LED, ηᵢₙ is the in-coupling efficiency of display light from the micro-LED into the waveguide and may be a product of the light collection efficiency of the light collection optics (e.g., a lens) in the display system and the coupling efficiency of the collected light into the waveguide (e.g., by a grating coupler), and ηₒᵤₜ is the out-coupling efficiency of the display light from the waveguide towards the user's eye. Thus, the overall efficiency ηₜₒₜ can be improved by improving one or more of η_{EQE}, ηᵢₙ, and ηₒᵤₜ.

In semiconductor LEDs, photons are usually generated at a certain internal quantum efficiency through the recombination of electrons and holes within an active region (e.g., one or more semiconductor layers), where the internal quantum efficiency is the proportion of the electron-hole recombination in the active region that emits photons. The generated light may then be extracted from the LEDs in a particular direction or within a particular solid angle. The ratio between the number of emitted photons extracted from an LED and the number of electrons passing through the LED is referred to as the external quantum efficiency, which describes how efficiently the LED converts injected electrons to photons that are extracted from the device.

In some embodiments, to increase the light extraction efficiency and thus the external quantum efficiency, one or more other optical components, such as a lens, may be formed on the light emission surface, such as substrate 710 or 710′, to extract the emitted light within a certain solid angle out of an LED, and/or to focus or collimate the emitted light. For example, in some embodiments, a micro-lens array may be formed on a micro-LED array, where the light emitted from each micro-LED may be collected and extracted by one or one micro-lenses, and may be collimated, focused, or expanded, and then directed to a waveguide in a waveguide-based display system. The micro-lenses may help to increase the light collection efficiency and thus improve the coupling efficiency and the overall efficiency of the display system.

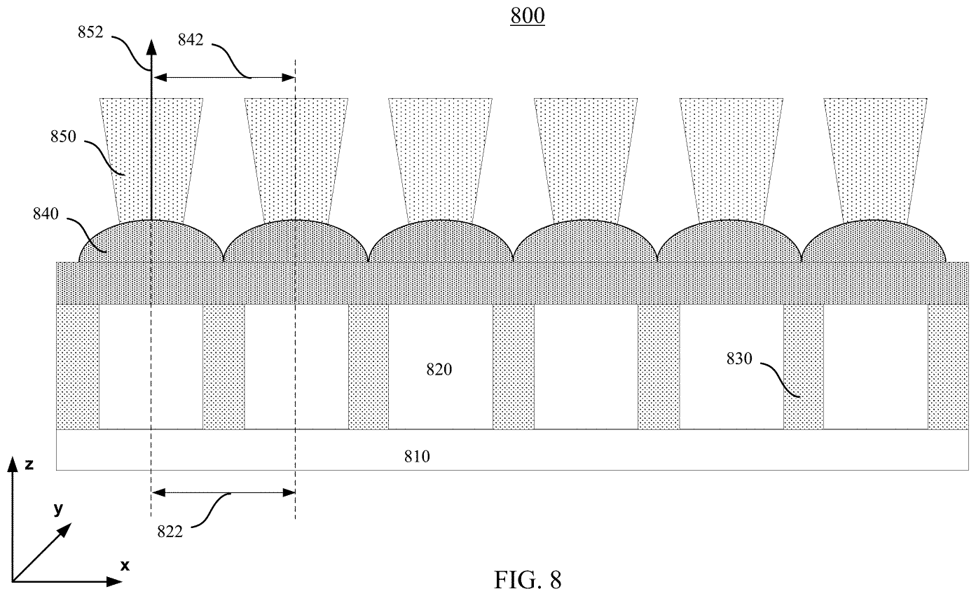

FIG. 8 illustrates an example of a device 800 including a micro-LED array 820 and a micro-lens array 840 for light extraction from micro-LED array 820. Micro-LED array 820 may include a one-dimensional or two-dimensional array of micro-LEDs, where the micro-LEDs may be uniformly distributed and may be separated by, for example, insulators 830, conductors, or any combinations thereof. Micro-LED array 820 may include epitaxial structures formed on a substrate 810, or a metal and/or insulator layer formed on substrate 810, as described above with respect to, for example, FIGS. 7A and 7B. Insulators 830 may include, for example, passivation layers (e.g., passivation layer 770), light reflection layers, filling materials (e.g., polymers), and the like.

Micro-lens array 840 may be formed directly on micro-LED array 820 or may be formed on a substrate and then bonded to micro-LED array 820. For example, micro-lens array 840 may be etched in a dielectric layer of micro-LED array 820, such as a substrate or an oxide layer (e.g., a SiO₂ layer) of micro-LED array 820, or may be formed on a dielectric layer deposited on micro-LED array 820, such as an oxide layer or a polymer layer, as described in detail below. In the example shown in FIG. 8, micro-lens array 840 may align with micro-LED array 820, where a pitch 822 of micro-LED array 820 may be the same as the pitch 842 of micro-lens array 840, and the optical axis of each micro-lens in micro-lens array 840 may align with a center of a respective micro-LED in micro-LED array 820. Thus, the chief ray of the light from each micro-LED after passing through the corresponding micro-lens may be the same, such as in the direction of the optical axis or perpendicular to micro-LED array 820.

As shown in FIG. 8, alight beam 850 from each micro-lens in micro-lens array 840 may have a chief ray 852 aligned with the optical axis of the corresponding micro-lens. For example, chief ray 852 of light beam 850 may be at 90 with respect to micro-lens array 840 or micro-LED array 820. The focal length and the distance of the micro-lenses from the corresponding micro-LEDs may be configured such that light beam 850 may be a collimated beam, a converging beam, or a diverging beam.

In some embodiments, pitch 822 of micro-LED array 820 may be the same as pitch 842 of micro-lens array 840, but micro-lens array 840 may not be align with micro-LED array 820, where the optical axis of each micro-lens in micro-lens array 840 may be offset from the center of a respective micro-LED in micro-LED array 820. As such, the chief ray of each light beam after passing through the respective micro-lens may not align with the optical axis of each micro-lens. However, because the pitch matching, the chief rays of the light beams after passing through micro-lens array 840 may be in the same direction. In some embodiments, to improve the in-coupling efficiency of display light from the micro-LED into a waveguide-based display system, it may be desirable that the light from each micro-LED is directed to the waveguide at a different respective angle.

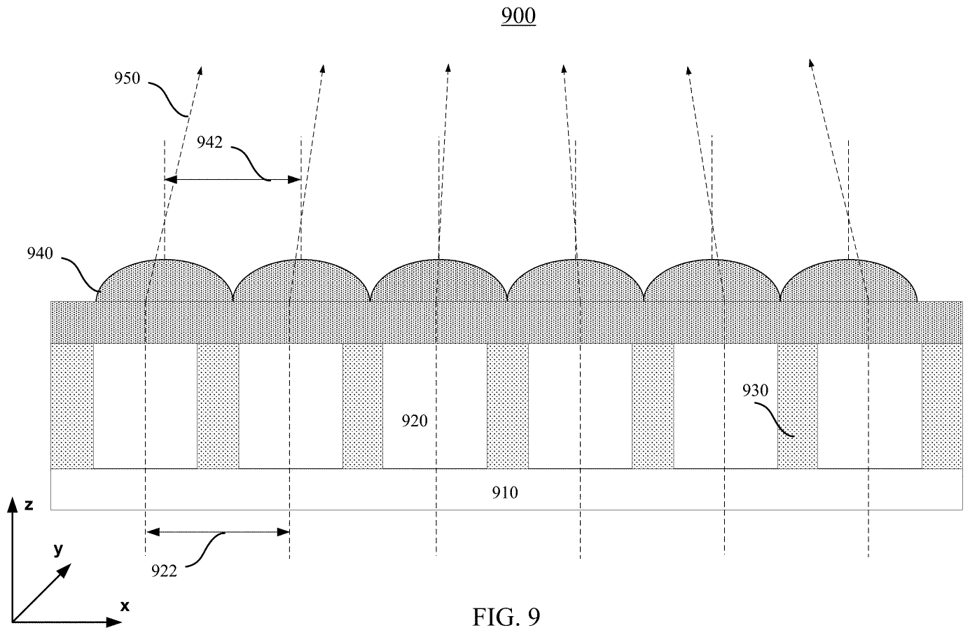

FIG. 9 illustrates an example of a device 900 including a micro-LED array 920 and a micro-lens array 940 for extracting and converging light from micro-LED array 920 according to certain embodiments. Micro-LED array 920 may include a one-dimensional or two-dimensional array of micro-LEDs, where the micro-LEDs may be uniformly distributed and may be separated by, for example, insulators 930, conductors, or any combinations of conductors and insulators. Micro-LED array 920 may include epitaxial structures formed on a substrate 910 as described above with respect to, for example, FIGS. 7A and 7B. Insulators 930 may include, for example, passivation layers (e.g., passivation layer 770), light reflection layers, filling materials (e.g., polymers), and the like.

Micro-lens array 940 may be formed directly on micro-LED array 920 or may be formed on a substrate and then bonded to micro-LED array 920. For example, micro-lens array 940 may be etched in a dielectric layer of micro-LED array 920, such as a substrate or an oxide layer (e.g., a SiO₂ layer) of micro-LED array 920, or may be formed on a dielectric layer deposited on micro-LED array 920, such as an oxide layer or a polymer layer, as described in detail below. The focal length and the distance of the micro-lenses from the corresponding micro-LEDs may be configured such that light beam from each micro-lens may be a collimated beam, a converging beam, or a diverging beam.

A pitch 922 of micro-LED array 920 may be different from (e.g., less than or greater than) a pitch 942 of micro-lens array 940, and thus the optical axis of each micro-lens in micro-lens array 940 may be offset from the center of a respective micro-LED in micro-LED array 920 by a different distance. As such, the chief ray 950 of the light from each micro-LED after passing through the corresponding micro-lens may be different. In the example shown in FIG. 9, pitch 922 of micro-LED array 920 may be greater than pitch 942 of micro-lens array 940, and thus the optical axis of each micro-lens in micro-lens array 940 may be offset from the center of a respective micro-LED in micro-LED array 920 by a different distance. The offset may be a function of the location of the micro-lens. For example, the offset may linearly increase as a function of the distance of the micro-lens from the center of device 900, and thus the angle of chief ray 950 of a micro-LED with respect to the surface-normal direction of micro-LED array 920 may gradually increase as the distance of the micro-LED from the center of device 900 increases. As a result, the chief rays 950 of the light from the micro-LEDs after passing through the corresponding micro-lenses may be in different directions towards the middle line of micro-LED array 920 and may converge as shown in the example.

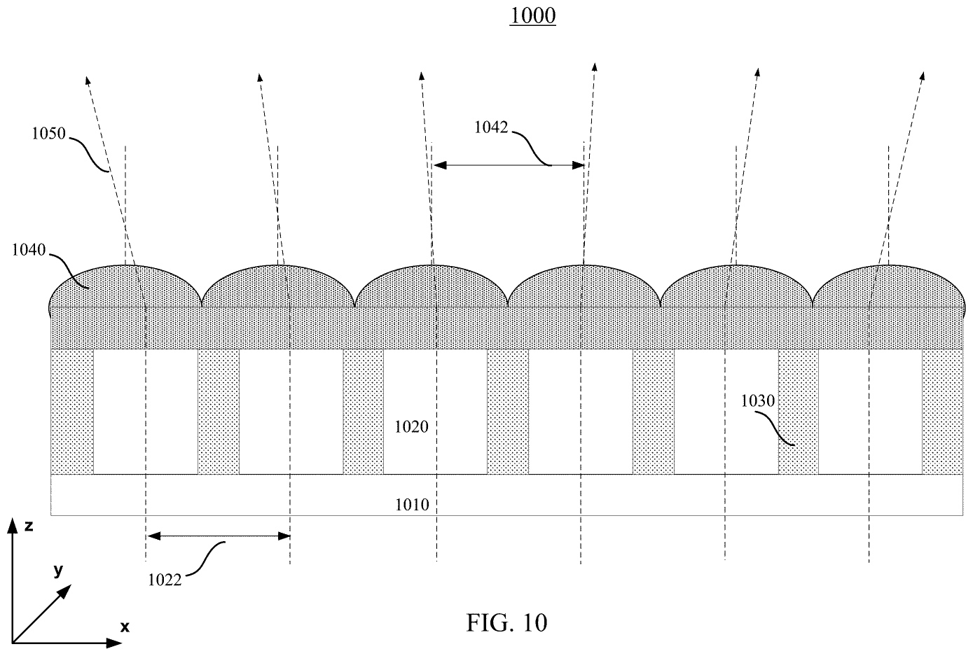

FIG. 10 illustrates an example of a device 1000 including a micro-LED array 1020 and a micro-lens array 1040 for extracting and converging light from micro-LED array 1020 according to certain embodiments. Micro-LED array 1020 may include a one-dimensional or two-dimensional array of micro-LEDs, where the micro-LEDs may be uniformly distributed and may be separated by, for example, insulators 1030, conductors, or any combinations of conductors and insulators. Micro-LED array 1020 may include epitaxial structures formed on a substrate 1010 as described above with respect to, for example, FIGS. 7A and 7B. Insulators 1030 may include, for example, passivation layers (e.g., passivation layer 770), light reflection layers, filling materials (e.g., polymers), and the like.

Micro-lens array 1040 may be formed directly on micro-LED array 1020 or may be formed on a substrate and then bonded to micro-LED array 1020. For example, micro-lens array 1040 may be etched in a dielectric layer of micro-LED array 1020, such as a substrate or an oxide layer (e.g., a SiO₂ layer) of micro-LED array 1020, or may be formed on a dielectric layer deposited on micro-LED array 1020, such as an oxide layer or a polymer layer, as described in detail below. The focal length and the distance of the micro-lenses from the corresponding micro-LEDs may be configured such that light beam from each micro-lens may be a collimated beam, a converging beam, or a diverging beam.

A pitch 1022 of micro-LED array 1020 may be different from (e.g., less than or greater than) a pitch 1042 of micro-lens array 1040, and thus the optical axis of each micro-lens in micro-lens array 1040 may be offset from the center of a respective micro-LED in micro-LED array 1020 by a different distance. As such, the chief ray 1050 of the light from each micro-LED after passing through the corresponding micro-lens may be different. In the example shown in FIG. 10, pitch 1022 of micro-LED array 1020 may be less than the pitch 1042 of micro-lens array 1040, and thus the optical axis of each micro-lens in micro-lens array 1040 may be offset from the center of a respective micro-LED in micro-LED array 1020 by a different distance. The offset may be a function of the location of the micro-lens. For example, the offset may linearly increase as a function of the distance of the micro-lens from the center of device 1000. As a result, the chief rays 1050 of the light from the micro-LEDs after passing through the corresponding micro-lenses may be in different directions and may diverge as shown in the example.

In various embodiments, the pitch of micro-lens array may be uniform or non-uniform. For example, the pitch of a two-dimensional micro-lens array may be uniform in two orthogonal directions, uniform in one direction only, or non-uniform in both directions. The pitch may also be the same or different in the two orthogonal directions.

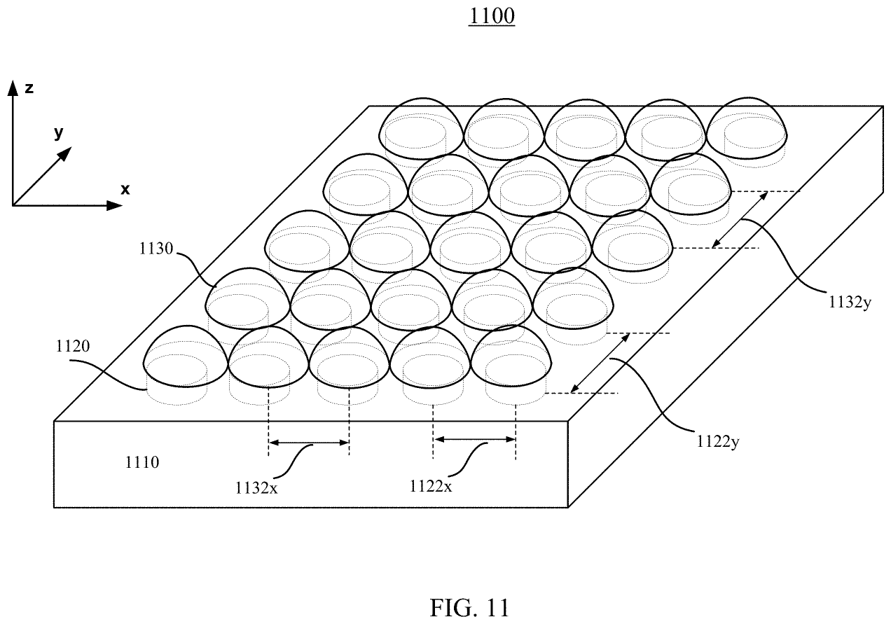

FIG. 11 illustrates an example of a device 1100 including a two-dimensional micro-LED array 1120 and a two-dimensional micro-lens array 1130 for extracting light from two-dimensional micro-LED array 1120 according to certain embodiments. Two-dimensional micro-LED array 1120 may include epitaxial structures fabricated on a substrate 1110 as described above. 2-D micro-LED array 1120 may be characterized by a pitch 1122x in the x-direction and a pitch 1122y in the y-direction, where pitch 1122x and pitch 1122y may be the same or may be different, and each of pitch 1122x and pitch 1122y may be constant or may vary across two-dimensional micro-LED array 1120.

2-D micro-lens array 1130 may be formed on 2-D micro-LED array 1120, where each micro-lens in 2-D micro-lens array 1130 may correspond to each respective micro-LED in 2-D micro-LED array 1120. 2-D micro-lens array 1130 may be characterized by a pitch 1132x in the x-direction and a pitch 1132y in the y-direction, where pitch 1132x and pitch 1132y may be the same or may be different. Pitch 1132x may be different from pitch 1122x, and/or pitch 1132y may be different from pitch 1122y. As described above, the pitch of two-dimensional micro-lens array 1130 may be uniform in two orthogonal directions, uniform in one direction only, or non-uniform in both directions, such as varying in one or two dimensions (e.g., x and/or y direction).

As described above with respect to FIGS. 9 and 10, the chief rays from 2-D micro-lens array 1130 may converge in the x-direction when pitch 1132x is less than pitch 1122x, and may diverge in the x-direction when pitch 1132x is greater than pitch 1122x. Similarly, the chief rays from 2-D micro-lens array 1130 may converge in the y-direction when pitch 1132y is less than pitch 1122y, and may diverge in the y-direction when pitch 1132y is greater than pitch 1122y.

The micro-lens arrays described above may be fabricated by, for example, reflowing patterned polymers (e.g., photoresist) or using a gray-scale photomask and a photoresist with a linear response to exposure dosage to form the micro-lens array in the photoresist, and/or dry etching the polymers or photoresist to transfer the pattern and shape of the micro-lens array to a dielectric material layer (e.g., a substrate or a dielectric layer).

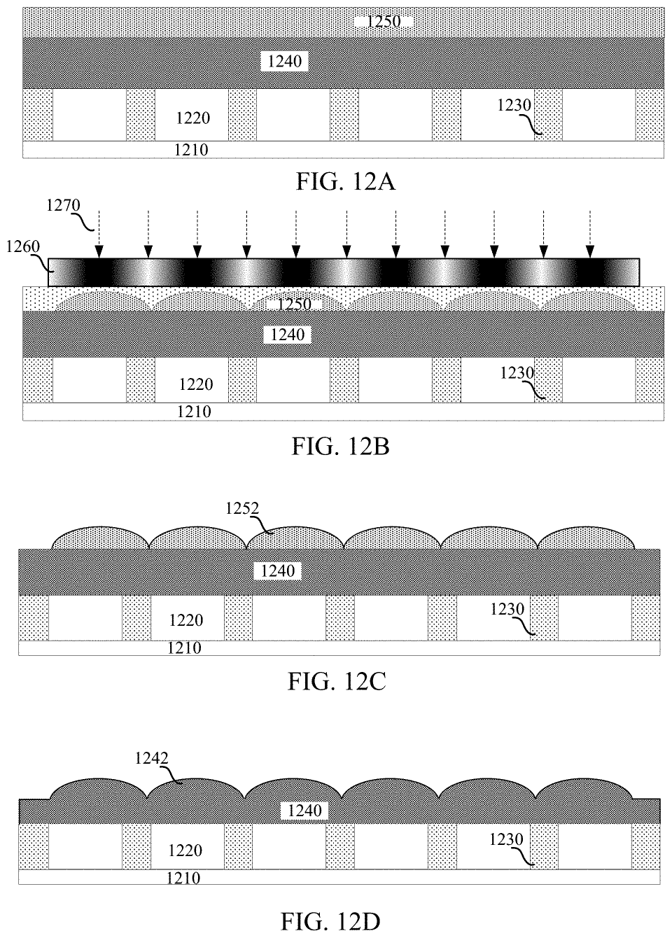

FIGS. 12A-12D illustrate an example of a method for fabricating an array of micro-lenses for light extraction from a micro-LED array according to certain embodiments. FIG. 12A illustrates an example of a micro-LED array device that includes a substrate 1210, an array of micro-LEDs 1220, and insulators and/or conductors 1230 between adjacent micro-LEDs 1220. The surface of the array of micro-LEDs 1220 and insulators and/or conductors 1230 may be planarized by, for example, chemical mechanical polishing (CMP), selective etching, or the like. A dielectric layer 1240 (e.g., a silicon dioxide or silicon nitride layer) may be deposited on the planarized surface of the array of micro-LEDs 1220 by, for example, plasma-enhanced chemical vapor deposition (PECVD), atomic layer deposition, or the like.

A photoresist layer 1250 may be deposited on dielectric layer 1240 by, for example, spin coating, spraying coating, physical vapor deposition, chemical vapor deposition, atomic layer deposition, or the like. Photoresist layer 1250 may have a low contrast or a linear response to light (e.g., ultraviolet light) exposure dose such that a depth of an exposed portion of photoresist layer 1250 may correlate with the exposure dose, such as being a linear function of the exposure dose. Photoresist layer 1250 may include a positive or negative photoresist material. For example, photoresist layer 1250 may include a positive photoresist material, where the portion of the photoresist material that is exposed to light may become soluble to a photoresist developer, while the unexposed portion of the photoresist material may remain insoluble to the photoresist developer. The positive photoresist material may include a photodecomposing photoresist that may generate hydrophilic products after exposure. In some embodiments, photoresist layer 1250 may include a negative photoresist material, such as a photopolymeric photoresist or a photocrosslinking photoresist, which may polymerize or crosslink upon exposure to light to generate polymers or large networks that are not soluble in photoresist developers. In addition, the photoresist material in photoresist layer 1250 may be etched by the same etching process that etches the underlying dielectric layer 1240. In some embodiments, the photoresist material in photoresist layer 1250 may have an etch rate similar to the etch rate of dielectric layer 1240 (e.g., SiO₂ or Si₃N₄) using a same etching process, such that the thickness profile of the remaining photoresist material in photoresist layer 1250 may be transferred to dielectric layer 1240 by the etching process.

FIG. 12B shows that a gray-scale mask 1260 may be used to expose photoresist layer 1250 to exposure light 1270, such as UV light. In the example shown in FIG. 12B, photoresist layer 1250 may include a positive photoresist. Gray-scale mask 1260 may include a light transmissivity pattern, where certain regions of gray-scale mask 1260 may have higher transmissivity than other regions and the transmissivity may vary gradually from the high transmissivity regions to the low transmissivity regions. The light transmissivity profile of gray-scale mask 1260 may be complementary to the height profile or optical length profile of an array of micro-lenses. Exposure light 1270 may have a uniform intensity. Thus, after the exposure, the exposed portions of photoresist layer 1250 may have a depth profile corresponding to the light transmissivity profile of gray-scale mask 1260, and thus may be complementary to the height profile or optical length profile of an array of micro-lenses. The exposed portions of photoresist layer 1250 may change the chemical structure (e.g., decompose to smaller molecules) so that it may become more soluble in the developer. As shown in FIG. 12B, the unexposed portions of photoresist layer 1250 may have a thickness profile similar to the height profile or optical length profile of an array of micro-lenses, and may remain insoluble to the photoresist developer.

FIG. 12C illustrates that an array of micro-lenses 1252 may be formed in photoresist layer 1250 after the photo-exposure shown in FIG. 12B and a photoresist development process. The array of micro-lenses 1252 may have a thickness profile similar to the desired thickness profile of the final micro-lens array in the dielectric layer if the photoresist material has a similar etch rate as the dielectric material, or may have a thickness profile different from (e.g., higher or lower than) the desired thickness profile of the final micro-lens array in the dielectric layer if the photoresist material has a higher or lower etch rate than the dielectric material. As described in detail below, in some embodiments, the array of micro-lenses 1252 formed in photoresist layer 1250 or another polymer layer may be used as the micro-lenses for extracting light from the array of micro-LEDs 1220. In some of such embodiments, dielectric layer 1240 may not be used and the array of micro-lenses 1252 formed in photoresist layer 1250 or another polymer layer may be in direct contact with the array of micro-LEDs 1220.

FIG. 12D illustrates that photoresist layer 1250 with the patterned array of micro-lenses 1252 and the underlying dielectric layer 1240 may be etched to linearly or nonlinearly transfer the thickness profile of the array of micro-lenses 1252 into dielectric layer 1240, depending on the relative etch rates of the photoresist material and the dielectric material, to form an array of micro-lenses 1242 in dielectric layer 1240. The etching may include, for example, a wet etching, an ion milling, a plasma based reactive ion etching, or any combinations thereof. The wet etching may include a chemical etching using a combination of acids, bases, and solvents at a range of temperatures and concentrations. The ion milling may include a physical removal of a portion of the patterned photoresist layer and the underlying dielectric layer at an extremely low pressure and using a high accelerating potential such that electrons may be accelerated to impact gas atoms with enough energy to ionize the gas atoms. The plasma based reactive ion etching (RIE) may use a chemically reactive plasma at a low pressure and an electromagnetic field to remove portions of the patterned photoresist layer and the substrate. In any of these etching techniques, the etch rate of the photoresist material may be similar or comparable to the etch rate of the dielectric material in order to transfer the thickness profile of the patterned photoresist layer to the substrate. For example, the etch rate of the patterned photoresist layer 1250 may be between about 0.2 to about 5 times of the etch rate of dielectric layer 1240, between about 0.3 to about 3 times of the etch rate of dielectric layer 1240, between about 0.5 to about 2 times of the etch rate of dielectric layer 1240, between about 0.7 to about 1.5 times of the etch rate of dielectric layer 1240, between about 0.8 to about 1.2 times of the etch rate of the substrate, and the like.

The array of micro-lenses 1242 in dielectric layer 1240 may have a pitch different from the pitch of the array of micro-LEDs 1220. In the example shown in FIG. 12D, the array of micro-lenses 1242 in dielectric layer 1240 may have a pitch less than the pitch of the array of micro-LEDs 1220, and thus the chief rays of the light from micro-LEDs 1220 after passing through the corresponding micro-lenses 1242 may be in different directions and may converge as shown in FIG. 9.

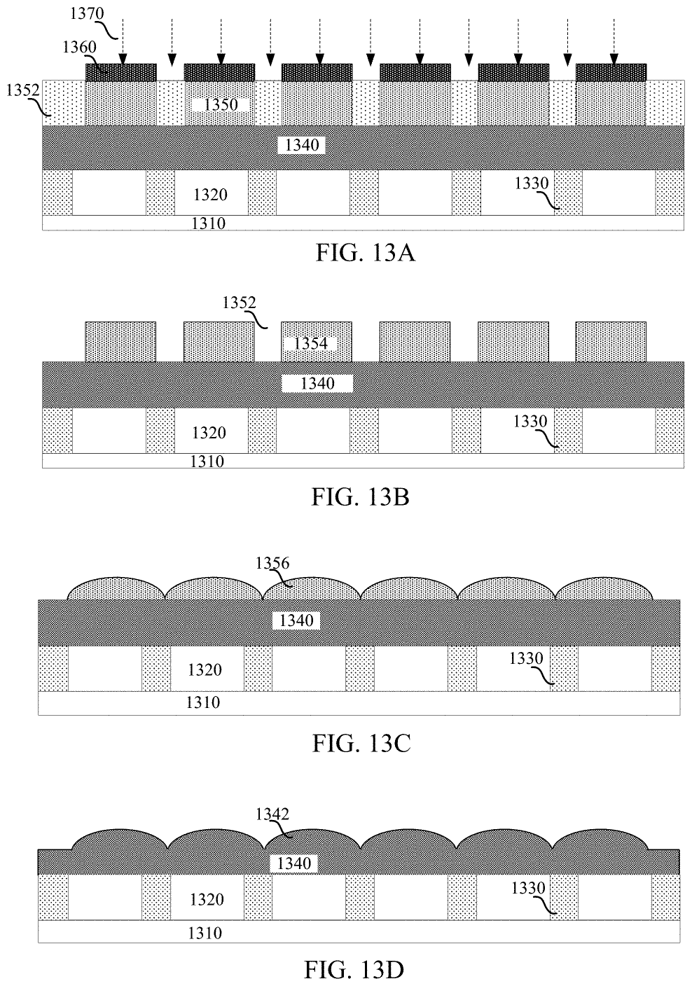

FIGS. 13A-13D illustrate an example of a method for fabricating an array of micro-lenses for light extraction from a micro-LED array according to certain embodiments. FIG. 13A illustrates an example of a micro-LED array device that includes a substrate 1310, an array of micro-LEDs 1320, and insulators and/or conductors 1330 between adjacent micro-LEDS 1320. The surface of the array of micro-LEDs 1320 and insulators and/or conductors 1330 may be planarized by, for example, CMP, selective etching, or the like. A dielectric layer 1340 (e.g., a silicon dioxide or silicon nitride layer) may be deposited on the planarized surface of the array of micro-LEDs 1320 by, for example, PECVD, ALD, or the like.

A photoresist layer 1350 may be deposited on dielectric layer 1340 by, for example, spin coating, spraying coating, physical vapor deposition, chemical vapor deposition, atomic layer deposition, or the like. Photoresist layer 1350 may include a positive or negative photoresist material as described above. For example, photoresist layer 1350 may include a positive photoresist material, where the portion of the photoresist material that is exposed to light may become soluble to a photoresist developer, while the unexposed portion of the photoresist material may remain insoluble to the photoresist developer. The photoresist material in photoresist layer 1350 may be etched by the same etching process that etches the underlying dielectric layer 1340. The photoresist material in photoresist layer 1350 may have an etch rate similar or comparable to the etch rate of dielectric layer 1340 (e.g., SiO₂ or Si₃N₄) using a same etching process, such that the thickness profile of the photoresist material in photoresist layer 1350 may be transferred to dielectric layer 1340 by the etching process.

A photomask 1360 may be used to expose photoresist layer 1350 to exposure light 1370, such as UV light. Photomask 1360 may have a binary light transmissivity pattern, where certain regions of photomask 1360 may be transparent to exposure light 1370 and may allow exposure light 1370 to pass through, while other regions may be non-transparent to exposure light 1370 and thus may block exposure light 1370 from reaching the underlying portions of photoresist layer 1350. The binary light transmissivity pattern may have a light transmissivity profile similar to the light transmissivity of a binary grating, and may be characterized by a grating period or pitch less than a pitch of the array of micro-LEDs 1320. Exposure light 1370 may have a uniform intensity. Thus, after the exposure, the exposed portions 1352 of photoresist layer 1350 may change the chemical structure (e.g., decompose to smaller molecules) and thus may become more soluble to the photoresist developer, while the unexposed portions 1354 of photoresist layer 1350 may remain insoluble to the photoresist developer.

FIG. 13B illustrates that a pattern of photoresist material may be formed in photoresist layer 1350 after the photo-exposure shown in FIG. 13A and a photoresist development process. The exposed portions 1352 of photoresist layer 1350 may be removed during the photoresist development process, while the remaining portions 1354 of photoresist layer 1350 may form a grating structure. Because the pitch of the transmissivity profile of photomask 1360 is different from the pitch of the array of micro-LEDs 1320, the grating structure formed by the remaining portions 1354 of photoresist layer 1350 may have a pitch from the pitch of the array of micro-LEDs 1320.

FIG. 13C illustrates that the remaining portions 1354 of photoresist layer 1350 may go through a thermal reflow process. For example, the remaining portions 1354 of photoresist layer 1350 may be heated from the top or bottom of the array of micro-LEDs 1320 to a temperature slight above the melting point of photoresist layer 1350, such that the photoresist may be liquefied. The melted photoresist material may reflow and reach an equilibrium state governed by the surface tension of the liquid photoresist material. The equilibrium state may be a spherical cap for a particular photoresist volume, depending on the contact angle of the photoresist material on the surface of dielectric layer 1340. After reaching the equilibrium state, the photoresist material may be allowed to cool down and solidify to form an array of micro-lenses 1356 in photoresist layer 1350. The array of micro-lenses 1356 may be used as the micro-lenses for extracting light from the array of micro-LEDs 1320, or may be used as a mask layer for etching the underlying dielectric layer 1340.

FIG. 13D illustrates that photoresist layer 1350 with the array of micro-lenses 1356 and the underlying dielectric layer 1340 may optionally be etched to linearly or nonlinearly transfer the thickness profile of the array of micro-lenses 1356 into dielectric layer 1340, depending on the relative etch rates of the photoresist material and the dielectric material, to form an array of micro-lenses 1342 in dielectric layer 1340. As described above with respect to FIG. 12D, the etching may include, for example, a wet etching, an ion milling, a plasma based reactive ion etching, or any combinations thereof. In any of these etching techniques, the etch rate of the photoresist material may be similar or comparable to the etch rate of the dielectric material to transfer the thickness profile of the patterned photoresist layer to the substrate. For example, the etch rate of the patterned photoresist layer 1350 may be between about 0.2 to about 5 times of the etch rate of dielectric layer 1340, between about 0.3 to about 3 times of the etch rate of dielectric layer 1340, between about 0.5 to about 2 times of the etch rate of dielectric layer 1340, between about 0.7 to about 1.5 times of the etch rate of dielectric layer 1340, between about 0.8 to about 1.2 times of the etch rate of dielectric layer 1340, and the like.

The array of micro-lenses 1342 in dielectric layer 1340 may have a pitch different from the pitch of the array of micro-LEDs 1320. In the example shown in FIG. 13D, the array of micro-lenses 1342 in dielectric layer 1340 may have a pitch less than the pitch of the array of micro-LEDs 1320, and thus the chief rays of the light from micro-LEDs 1320 after passing through the corresponding micro-lenses 1342 may be in different directions and may converge as shown in FIG. 9.

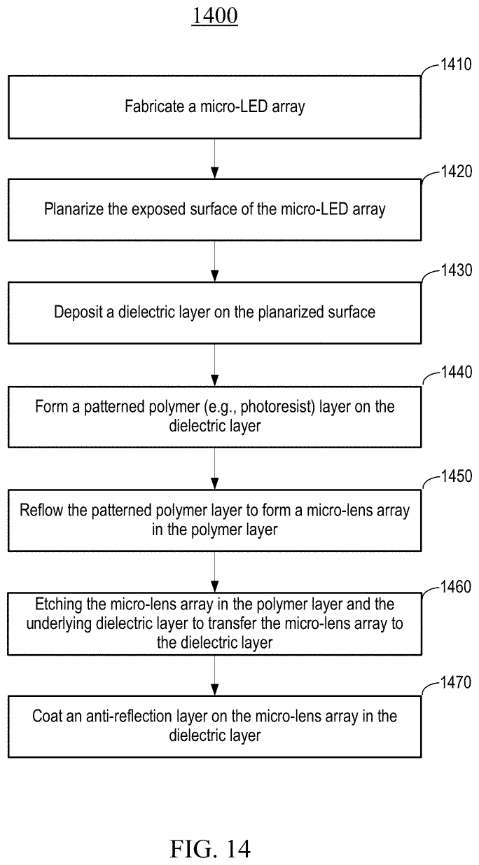

FIG. 14 is a flow chart 1400 illustrating an example of a method for fabricating an array of micro-lenses for light extraction from a micro-LED array using a thermal reflow process according to certain embodiments. The operations described in flow chart 1400 are for illustration purposes only and are not intended to be limiting. In various implementations, modifications may be made to flow chart 1400 to add additional operations or to omit some operations. The operations described in flow chart 1400 may be performed by, for example, one or more semiconductor fabrication systems that include a patterning system, a deposition system, an etching system, or any combination thereof.

At block 1410, a micro-LED array may be fabricated as described above with respect to, for example, FIGS. 5A, 5B, 7A, and 7B. Each micro-LED in the micro-LED array may include a heterostructure (e.g., a MQW) that includes multiple layers, such as GaN, InGaN, AlGaN, or AlInGaP layers, epitaxially grown on a substrate with a certain crystal lattice orientation (e.g., polar, nonpolar, or semi-polar orientation), such as a GaN, GaAs, or GaP substrate, or a substrate including, but not limited to, sapphire, silicon carbide, silicon, zinc oxide, boron nitride, lithium aluminate, lithium niobate, germanium, aluminum nitride, lithium gallate, partially substituted spinels, or quaternary tetragonal oxides sharing the beta-LiAlO₂ structure. The substrate may be cut in a specific direction to expose a specific plane as the growth surface. Each micro-LED may include a mesa structure of any desired shape and a passivation layer (e.g., a SiO₂ layer and/or a metal layer) surrounding the mesa structure as described above. Adjacent micro-LED may be isolated by, for example, insulation materials or metals with some dielectric materials, such as the passivation layer, resin, or the like. The linear dimension of each micro-LED may be a few microns (e.g., less than about 10 μm, such as about 1-5 μm) or a few tens of microns. The micro-lens array may also be encapsulated by a dielectric material layer.

Optionally, at block 1420, the exposed surface of the micro-LED array, such as the surface of the encapsulation layer, the substrate, or another surface through which the light emitted by the micro-LED array may be extracted, may be planarized by, for example, CMP, selective etching, or other processes, to achieve a flat and smooth surface.

Optionally, at block 1430, a dielectric layer, such as a SiO₂ or SiN_{X} layer, may be deposited on the planarized surface of the micro-LED array by, for example, PECVD, ALD, or the like. A thickness of the dielectric layer may be higher than the desired thickness of the micro-lens array to be fabricated.

At block 1440, a patterned polymer layer may be formed on the dielectric layer. The pitch of the pattern in the patterned polymer layer may be slightly different from the pitch of the micro-LED array, such that the center of each off-centered polymer region in the patterned polymer layer may not be aligned with the center of the corresponding micro-LED in the micro-lens array. The etch rate of the polymer may be similar to or comparable to the etch rate of the dielectric layer under the patterned polymer layer. In some embodiments, the polymer layer may include a positive or negative photoresist, and the pattern in the patterned polymer (e.g., photoresist) layer may be formed by a photolithography process using a binary mask and exposure light (e.g., UV light) as described above with respect to, for example, FIG. 13A. In some embodiments, the pattern in the patterned polymer layer may be formed by a printing process where a certain volume of polymer may be deposited at each location of a one- or two-dimensional array of locations with a certain distance between adjacent locations.

At block 1450, the patterned polymer layer may go through a reflow process to form a micro-lens array in the polymer material. For example, the patterned polymer layer may be heated from the top or bottom of the micro-LED array to a temperature slight above the melting point of the patterned polymer layer, such that the polymer material may be liquefied and allowed to flow. The melted polymer material may reflow and reach an equilibrium state due to the surface tension of the liquid polymer material. The equilibrium state may be a spherical cap for a particular polymer volume, depending on the contact angle of the polymer material on the surface of the dielectric layer. After reaching the equilibrium state, the polymer material may be allowed to cool down and solidify to form an array of micro-lenses including the polymer material. The array of micro-lenses formed by the polymer material may be used as the micro-lens array for extracting light from the micro-LED array, or may be used as a mask layer for etching the underlying dielectric layer.

Optionally, at block 1460, the micro-lens array in the polymer material and the underlying dielectric layer may be etched to transfer the micro-lens array to the dielectric layer. The etching may include, for example, an ion milling, a plasma-based reactive ion etching (e.g., RIE), or another dry etching process. The etch rate of the polymer material may be similar to or comparable to the etch rate of the dielectric material, in order to more linearly transfer the thickness profile of the patterned polymer layer to the substrate. For example, the etch rate of the patterned polymer layer may be between about 0.2 to about 5 times of the etch rate of the dielectric layer, between about 0.3 to about 3 times of the etch rate of the dielectric layer, between about 0.5 to about 2 times of the etch rate of the dielectric layer, between about 0.7 to about 1.5 times of the etch rate of the dielectric layer, between about 0.8 to about 1.2 times of the etch rate of the dielectric layer, and the like.

Optionally, at block 1470, an anti-reflection layer may be coated on the micro-lens array in the dielectric layer. The anti-reflection layer may include one or more dielectric layers (e.g., thin films) that have certain refractive indices and/or thicknesses, such that the reflections at different interfaces of the one or more dielectric layers may destructively interfere to reduce the reflection. For example, the dielectric layers may include tantalum pentoxide (Ta₂O₅) and aluminum oxide (Al₂O₃) in alternating thin layers. The one or more dielectric layers may be deposited on the surface of the micro-lens array by, for example, evaporative deposition, ion assisted deposition, plasma sputtering, ion beam sputtering, ALD, or the like.

One or two-dimensional arrays of the LEDs and micro-lenses described above may be manufactured on a wafer to form light sources (e.g., light source 642). Driver circuits (e.g., driver circuit 644) may be fabricated, for example, on a silicon wafer using CMOS processes. The LEDs and the driver circuits on wafers may be diced and then bonded together, or may be bonded on the wafer level and then diced. Various bonding techniques can be used for bonding the LEDs and the driver circuits, such as adhesive bonding, metal-to-metal bonding, metal oxide bonding, wafer-to-wafer bonding, die-to-wafer bonding, hybrid bonding, and the like.

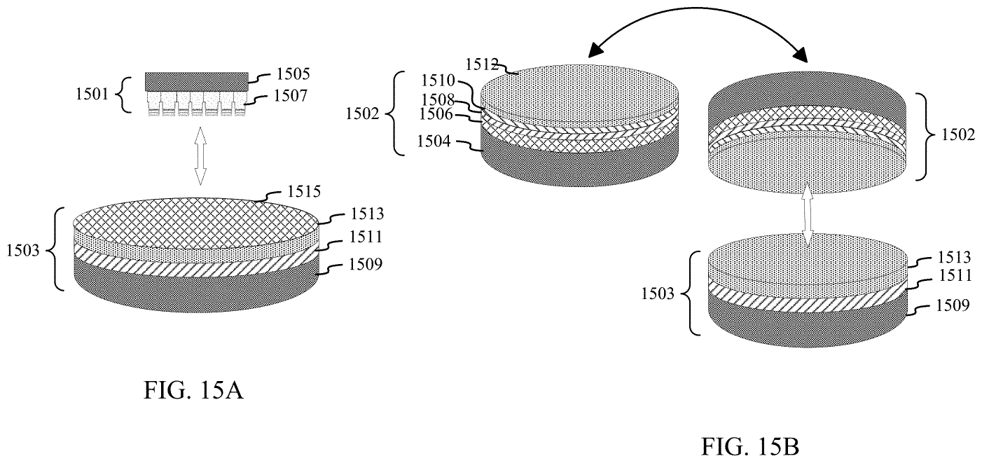

FIG. 15A illustrates an example of a method of die-to-wafer bonding for arrays of LEDs according to certain embodiments. In the example shown in FIG. 15A, an LED array 1501 may include a plurality of LEDs 1507 on a carrier substrate 1505. Carrier substrate 1505 may include various materials, such as GaAs, InP, GaN, AlN, sapphire, SiC, Si, or the like. LEDs 1507 may be fabricated by, for example, growing various epitaxial layers, forming mesa structures, and forming electrical contacts or electrodes, before performing the bonding. The epitaxial layers may include various materials, such as GaN, InGaN, (AlGaIn)P, (AlGaIn)AsP, (AlGaIn)AsN, (AlGaIn)Pas, (Eu:InGa)N, (AlGaIn)N, or the like, and may include an n-type layer, a p-type layer, and an active layer that includes one or more heterostructures, such as one or more quantum wells or MQWs. The electrical contacts may include various conductive materials, such as a metal or a metal alloy.

A wafer 1503 may include a base layer 1509 having passive or active integrated circuits (e.g., driver circuits 1511) fabricated thereon. Base layer 1509 may include, for example, a silicon wafer. Driver circuits 1511 may be used to control the operations of LEDs 1507. For example, the driver circuit for each LED 1507 may include a 2T1C pixel structure that has two transistors and one capacitor. Wafer 1503 may also include a bonding layer 1513. Bonding layer 1513 may include various materials, such as a metal, an oxide, a dielectric, CuSn, AuTi, and the like. In some embodiments, a patterned layer 1515 may be formed on a surface of bonding layer 1513, where patterned layer 1515 may include a metallic grid made of a conductive material, such as Cu, Ag, Au, Al, or the like.

LED array 1501 may be bonded to wafer 1503 via bonding layer 1513 or patterned layer 1515. For example, patterned layer 1515 may include metal pads or bumps made of various materials, such as CuSn, AuSn, or nanoporous Au, that may be used to align LEDs 1507 of LED array 1501 with corresponding driver circuits 1511 on wafer 1503. In one example, LED array 1501 may be brought toward wafer 1503 until LEDs 1507 come into contact with respective metal pads or bumps corresponding to driver circuits 1511. Some or all of LEDs 1507 may be aligned with driver circuits 1511, and may then be bonded to wafer 1503 via patterned layer 1515 by various bonding techniques, such as metal-to-metal bonding. After LEDs 1507 have been bonded to wafer 1503, carrier substrate 1505 may be removed from LEDs 1507.

FIG. 15B illustrates an example of a method of wafer-to-wafer bonding for arrays of LEDs according to certain embodiments. As shown in FIG. 15B, a first wafer 1502 may include a substrate 1504, a first semiconductor layer 1506, active layers 1508, and a second semiconductor layer 1510. Substrate 1504 may include various materials, such as GaAs, InP, GaN, AlN, sapphire, SiC, Si, or the like. First semiconductor layer 1506, active layers 1508, and second semiconductor layer 1510 may include various semiconductor materials, such as GaN, InGaN, (AlGaIn)P, (AlGaIn)AsP, (AlGaIn)AsN, (AlGaIn)Pas, (Eu:InGa)N, (AlGaIn)N, or the like. In some embodiments, first semiconductor layer 1506 may be an n-type layer, and second semiconductor layer 1510 may be a p-type layer. For example, first semiconductor layer 1506 may be an n-doped GaN layer (e.g., doped with Si or Ge), and second semiconductor layer 1510 may be a p-doped GaN layer (e.g., doped with Mg, Ca, Zn, or Be). Active layers 1508 may include, for example, one or more GaN layers, one or more InGaN layers, one or more AlInGaP layers, and the like, which may form one or more heterostructures, such as one or more quantum wells or MQWs.

In some embodiments, first wafer 1502 may also include a bonding layer. Bonding layer 1512 may include various materials, such as a metal, an oxide, a dielectric, CuSn, AuTi, or the like. In one example, bonding layer 1512 may include p-contacts and/or n-contacts (not shown). In some embodiments, other layers may also be included on first wafer 1502, such as a buffer layer between substrate 1504 and first semiconductor layer 1506. The buffer layer may include various materials, such as polycrystalline GaN or AlN. In some embodiments, a contact layer may be between second semiconductor layer 1510 and bonding layer 1512. The contact layer may include any suitable material for providing an electrical contact to second semiconductor layer 1510 and/or first semiconductor layer 1506.

First wafer 1502 may be bonded to wafer 1503 that includes driver circuits 1511 and bonding layer 1513 as described above, via bonding layer 1513 and/or bonding layer 1512. Bonding layer 1512 and bonding layer 1513 may be made of the same material or different materials. Bonding layer 1513 and bonding layer 1512 may be substantially flat. First wafer 1502 may be bonded to wafer 1503 by various methods, such as metal-to-metal bonding, eutectic bonding, metal oxide bonding, anodic bonding, thermo-compression bonding, ultraviolet (UV) bonding, and/or fusion bonding.

As shown in FIG. 15B, first wafer 1502 may be bonded to wafer 1503 with the p-side (e.g., second semiconductor layer 1510) of first wafer 1502 facing down (i.e., toward wafer 1503). After bonding, substrate 1504 may be removed from first wafer 1502, and first wafer 1502 may then be processed from the n-side. The processing may include, for example, the formation of certain mesa shapes for individual LEDs, as well as the formation of optical components corresponding to the individual LEDs.

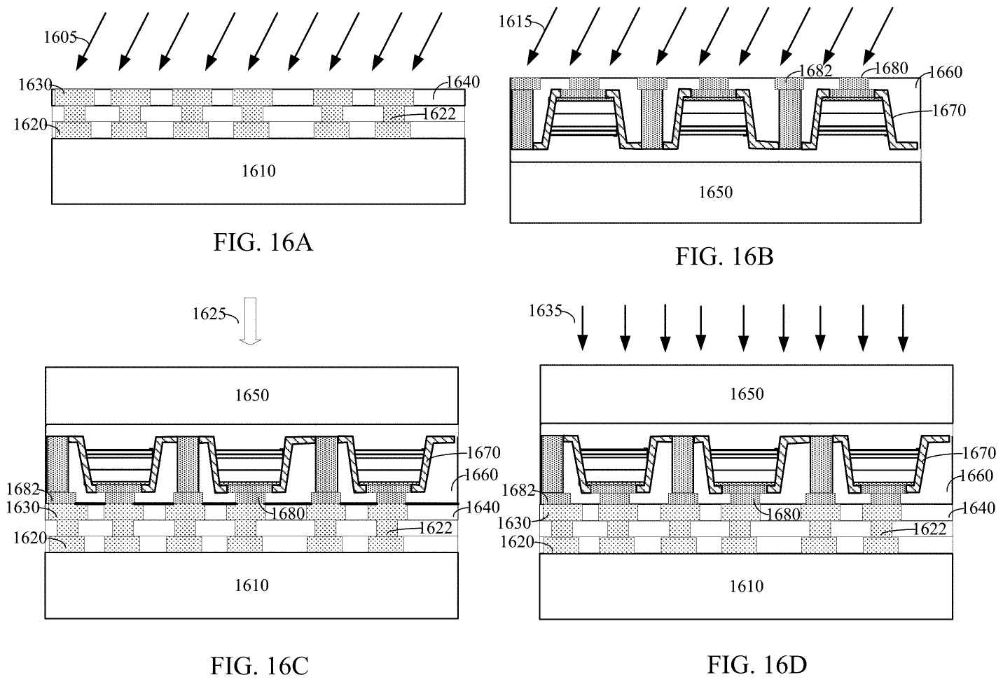

FIGS. 16A-16D illustrate an example of a method of hybrid bonding for arrays of LEDs according to certain embodiments. The hybrid bonding may generally include wafer cleaning and activation, high-precision alignment of contacts of one wafer with contacts of another wafer, dielectric bonding of dielectric materials at the surfaces of the wafers at room temperature, and metal bonding of the contacts by annealing at elevated temperatures. FIG. 16A shows a substrate 1610 with passive or active circuits 1620 manufactured thereon. As described above with respect to FIGS. 15A-15B, substrate 1610 may include, for example, a silicon wafer. Circuits 1620 may include driver circuits for the arrays of LEDs. A bonding layer may include dielectric regions 1640 and contact pads 1630 connected to circuits 1620 through electrical interconnects 1622. Contact pads 1630 may include, for example, Cu, Ag, Au, Al, W, Mo, Ni, Ti, Pt, Pd, or the like. Dielectric materials in dielectric regions 1640 may include SiCN, SiO₂, SiN, Al₂O₃, HfO₂, ZrO₂, Ta₂O₅, or the like. The bonding layer may be planarized and polished using, for example, chemical mechanical polishing, where the planarization or polishing may cause dishing (a bowl like profile) in the contact pads. The surfaces of the bonding layers may be cleaned and activated by, for example, an ion (e.g., plasma) or fast atom (e.g., Ar) beam 1605. The activated surface may be atomically clean and may be reactive for formation of direct bonds between wafers when they are brought into contact, for example, at room temperature.

FIG. 16B illustrates a wafer 1650 including an array of micro-LEDs 1670 fabricated thereon as described above with respect to, for example, FIGS. 7A-7B. Wafer 1650 may be a carrier wafer and may include, for example, GaAs, InP, GaN, AlN, sapphire, SiC, Si, or the like. Micro-LEDs 1670 may include an n-type layer, an active region, and a p-type layer epitaxially grown on wafer 1650. The epitaxial layers may include various III-V semiconductor materials described above, and may be processed from the p-type layer side to etch mesa structures in the epitaxial layers, such as substantially vertical structures, parabolic structures, conic structures, or the like. Passivation layers and/or reflection layers may be formed on the sidewalls of the mesa structures. P-contacts 1680 and n-contacts 1682 may be formed in a dielectric material layer 1660 deposited on the mesa structures and may make electrical contacts with the p-type layer and the n-type layers, respectively. Dielectric materials in dielectric material layer 1660 may include, for example, SiCN, SiO₂, SiN, Al₂O₃, HfO₂, ZrO₂, Ta₂O₅, or the like. P-contacts 1680 and n-contacts 1682 may include, for example, Cu, Ag, Au, Al, W, Mo, Ni, Ti, Pt, Pd, or the like. The top surfaces of p-contacts 1680, n-contacts 1682, and dielectric material layer 1660 may form a bonding layer. The bonding layer may be planarized and polished using, for example, chemical mechanical polishing, where the polishing may cause dishing in p-contacts 1680 and n-contacts 1682. The bonding layer may then be cleaned and activated by, for example, an ion (e.g., plasma) or fast atom (e.g., Ar) beam 1615. The activated surface may be atomically clean and reactive for formation of direct bonds between wafers when they are brought into contact, for example, at room temperature.

FIG. 16C illustrates a room temperature bonding process for bonding the dielectric materials in the bonding layers. For example, after the bonding layer that includes dielectric regions 1640 and contact pads 1630 and the bonding layer that includes p-contacts 1680, n-contacts 1682, and dielectric material layer 1660 are surface activated, wafer 1650 and micro-LEDs 1670 may be turned upside down and brought into contact with substrate 1610 and the circuits formed thereon. In some embodiments, compression pressure 1625 may be applied to substrate 1610 and wafer 1650 such that the bonding layers are pressed against each other. Due to the surface activation and the dishing in the contacts, dielectric regions 1640 and dielectric material layer 1660 may be in direct contact because of the surface attractive force, and may react and form chemical bonds between them because the surface atoms may have dangling bonds and may be in unstable energy states after the activation. Thus, the dielectric materials in dielectric regions 1640 and dielectric material layer 1660 may be bonded together with or without heat treatment or pressure.

FIG. 16D illustrates an annealing process for bonding the contacts in the bonding layers after bonding the dielectric materials in the bonding layers. For example, contact pads 1630 and p-contacts 1680 or n-contacts 1682 may be bonded together by annealing at, for example, about 200-400° C. or higher. During the annealing process, heat 1635 may cause the contacts to expand more than the dielectric materials (due to different coefficients of thermal expansion), and thus may close the dishing gaps between the contacts such that contact pads 1630 and p-contacts 1680 or n-contacts 1682 may be in contact and may form direct metallic bonds at the activated surfaces.

In some embodiments where the two bonded wafers include materials having different coefficients of thermal expansion (CTEs), the dielectric materials bonded at room temperature may help to reduce or prevent misalignment of the contact pads caused by the different thermal expansions. In some embodiments, to further reduce or avoid the misalignment of the contact pads at a high temperature during annealing, trenches may be formed between micro-LEDs, between groups of micro-LEDs, through part or all of the substrate, or the like, before bonding.

After the micro-LEDs are bonded to the driver circuits, the substrate on which the micro-LEDs are fabricated may be thinned or removed, and various secondary optical components may be fabricated on the light emitting surfaces of the micro-LEDs to, for example, extract, collimate, and redirect the light emitted from the active regions of the micro-LEDs. In one example, micro-lenses may be formed on the micro-LEDs, where each micro-lens may correspond to a respective micro-LED and may help to improve the light extraction efficiency and collimate the light emitted by the micro-LED. In some embodiments, the secondary optical components may be fabricated in the substrate or the n-type layer of the micro-LEDs. In some embodiments, the secondary optical components may be fabricated in a dielectric layer deposited on the n-type side of the micro-LEDs. Examples of the secondary optical components may include a lens, a grating, an antireflection (AR) coating, a prism, a photonic crystal, or the like.

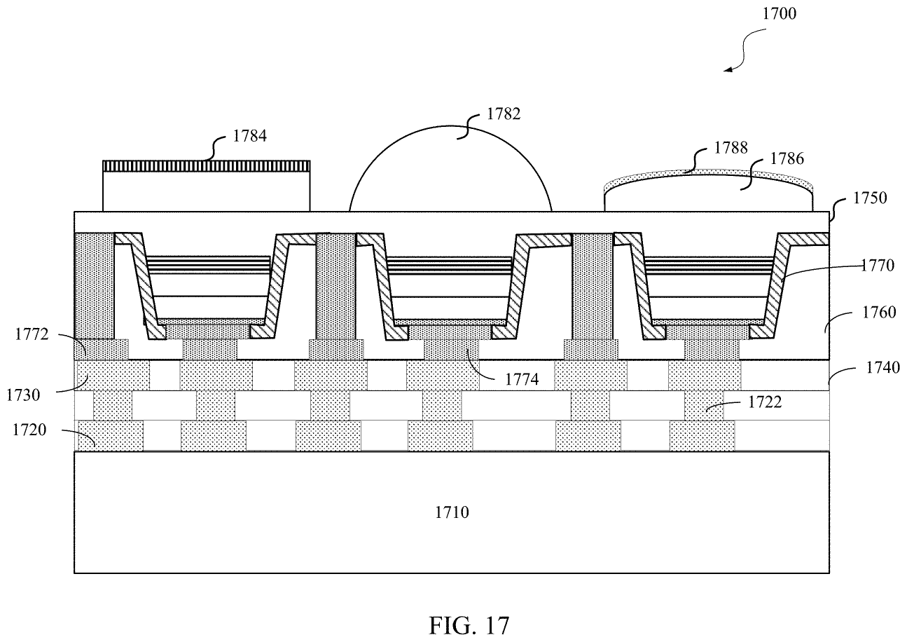

FIG. 17 illustrates an example of an LED array 1700 with secondary optical components fabricated thereon according to certain embodiments. LED array 1700 may be made by bonding an LED chip or wafer with a silicon wafer including electrical circuits fabricated thereon, using any suitable bonding techniques described above with respect to, for example, FIGS. 15A-16D. In the example shown in FIG. 17, LED array 1700 may be bonded using a wafer-to-wafer hybrid bonding technique as described above with respect to FIG. 16A-16D. LED array 1700 may include a substrate 1710, which may be, for example, a silicon wafer. Integrated circuits 1720, such as LED driver circuits, may be fabricated on substrate 1710. Integrated circuits 1720 may be connected to p-contacts 1774 and n-contacts 1772 of micro-LEDs 1770 through interconnects 1722 and contact pads 1730, where contact pads 1730 may form metallic bonds with p-contacts 1774 and n-contacts 1772. Dielectric layer 1740 on substrate 1710 may be bonded to dielectric layer 1760 through fusion bonding.

The substrate (not shown) of the LED chip or wafer may be thinned or may be removed to expose the n-type layer 1750 of micro-LEDs 1770. Various secondary optical components, such as a spherical micro-lens 1782, a grating 1784, a micro-lens 1786, an antireflection layer 1788, and the like, may be formed in or on top of n-type layer 1750. For example, spherical micro-lens arrays may be etched in the semiconductor materials of micro-LEDs 1770 using a gray-scale mask and a photoresist with a linear response to exposure light, or using an etch mask formed by thermal reflowing of a patterned photoresist layer. The secondary optical components may also be etched in a dielectric layer deposited on n-type layer 1750 using similar photolithographic techniques or other techniques. For example, micro-lens arrays may be formed in a polymer layer through thermal reflowing of the polymer layer that is patterned using a binary mask. The micro-lens arrays in the polymer layer may be used as the secondary optical components or may be used as the etch mask for transferring the profiles of the micro-lens arrays into a dielectric layer or a semiconductor layer. The dielectric layer may include, for example, SiCN, SiO₂, SiN, Al₂O₃, HfO₂, ZrO₂, Ta₂O₅, or the like. In some embodiments, a micro-LED 1770 may have multiple corresponding secondary optical components, such as a micro-lens and an anti-reflection coating, a micro-lens etched in the semiconductor material and a micro-lens etched in a dielectric material layer, a micro-lens and a grating, a spherical lens and an aspherical lens, and the like. Three different secondary optical components are illustrated in FIG. 17 to show some examples of secondary optical components that can be formed on micro-LEDs 1770, which does not necessary imply that different secondary optical components are used simultaneously for every LED array.

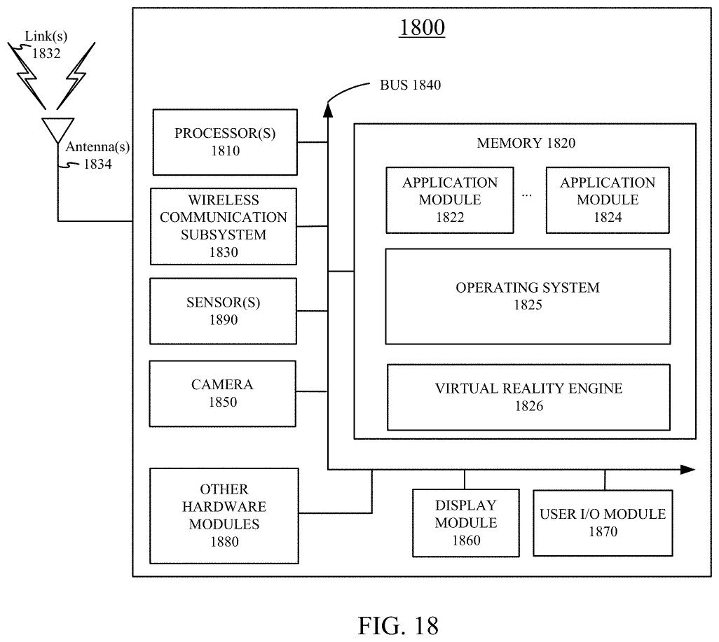

FIG. 18 is a simplified block diagram of an example electronic system 1800 of an example near-eye display (e.g., HMD device) for implementing some of the examples disclosed herein. Electronic system 1800 may be used as the electronic system of an HMD device or other near-eye displays described above. In this example, electronic system 1800 may include one or more processor(s) 1810 and a memory 1820. Processor(s) 1810 may be configured to execute instructions for performing operations at a number of components, and can be, for example, a general-purpose processor or microprocessor suitable for implementation within a portable electronic device. Processor(s) 1810 may be communicatively coupled with a plurality of components within electronic system 1800. To realize this communicative coupling, processor(s) 1810 may communicate with the other illustrated components across a bus 1840. Bus 1840 may be any subsystem adapted to transfer data within electronic system 1800. Bus 1840 may include a plurality of computer buses and additional circuitry to transfer data.

Memory 1820 may be coupled to processor(s) 1810. In some embodiments, memory 1820 may offer both short-term and long-term storage and may be divided into several units. Memory 1820 may be volatile, such as static random access memory (SRAM) and/or dynamic random access memory (DRAM) and/or non-volatile, such as read-only memory (ROM), flash memory, and the like. Furthermore, memory 1820 may include removable storage devices, such as secure digital (SD) cards. Memory 1820 may provide storage of computer-readable instructions, data structures, program modules, and other data for electronic system 1800. In some embodiments, memory 1820 may be distributed into different hardware modules. A set of instructions and/or code might be stored on memory 1820. The instructions might take the form of executable code that may be executable by electronic system 1800, and/or might take the form of source and/or installable code, which, upon compilation and/or installation on electronic system 1800 (e.g., using any of a variety of generally available compilers, installation programs, compression/decompression utilities, etc.), may take the form of executable code.

In some embodiments, memory 1820 may store a plurality of application modules 1822 through 1824, which may include any number of applications. Examples of applications may include gaming applications, conferencing applications, video playback applications, or other suitable applications. The applications may include a depth sensing function or eye tracking function. Application modules 1822-1824 may include particular instructions to be executed by processor(s) 1810. In some embodiments, certain applications or parts of application modules 1822-1824 may be executable by other hardware modules 1880. In certain embodiments, memory 1820 may additionally include secure memory, which may include additional security controls to prevent copying or other unauthorized access to secure information.

In some embodiments, memory 1820 may include an operating system 1825 loaded therein. Operating system 1825 may be operable to initiate the execution of the instructions provided by application modules 1822-1824 and/or manage other hardware modules 1880 as well as interfaces with a wireless communication subsystem 1830 which may include one or more wireless transceivers. Operating system 1825 may be adapted to perform other operations across the components of electronic system 1800 including threading, resource management, data storage control and other similar functionality.

Wireless communication subsystem 1830 may include, for example, an infrared communication device, a wireless communication device and/or chipset (such as a Bluetooth® device, an IEEE 802.11 device, a Wi-Fi device, a WiMax device, cellular communication facilities, etc.), and/or similar communication interfaces. Electronic system 1800 may include one or more antennas 1834 for wireless communication as part of wireless communication subsystem 1830 or as a separate component coupled to any portion of the system. Depending on desired functionality, wireless communication subsystem 1830 may include separate transceivers to communicate with base transceiver stations and other wireless devices and access points, which may include communicating with different data networks and/or network types, such as wireless wide-area networks (WWANs), wireless local area networks (WLANs), or wireless personal area networks (WPANs). A WWAN may be, for example, a WiMax (IEEE 802.16) network. A WLAN may be, for example, an IEEE 802.11x network. A WPAN may be, for example, a Bluetooth network, an IEEE 802.15x, or some other types of network. The techniques described herein may also be used for any combination of WWAN, WLAN, and/or WPAN. Wireless communications subsystem 1830 may permit data to be exchanged with a network, other computer systems, and/or any other devices described herein. Wireless communication subsystem 1830 may include a means for transmitting or receiving data, such as identifiers of HMD devices, position data, a geographic map, a heat map, photos, or videos, using antenna(s) 1834 and wireless link(s) 1832. Wireless communication subsystem 1830, processor(s) 1810, and memory 1820 may together comprise at least a part of one or more of a means for performing some functions disclosed herein.

Embodiments of electronic system 1800 may also include one or more sensors 1890. Sensor(s) 1890 may include, for example, an image sensor, an accelerometer, a pressure sensor, a temperature sensor, a proximity sensor, a magnetometer, a gyroscope, an inertial sensor (e.g., a module that combines an accelerometer and a gyroscope), an ambient light sensor, or any other similar module operable to provide sensory output and/or receive sensory input, such as a depth sensor or a position sensor. For example, in some implementations, sensor(s) 1890 may include one or more inertial measurement units (IMUs) and/or one or more position sensors. An IMU may generate calibration data indicating an estimated position of the HMD device relative to an initial position of the HMD device, based on measurement signals received from one or more of the position sensors. A position sensor may generate one or more measurement signals in response to motion of the HMD device. Examples of the position sensors may include, but are not limited to, one or more accelerometers, one or more gyroscopes, one or more magnetometers, another suitable type of sensor that detects motion, a type of sensor used for error correction of the IMU, or any combination thereof. The position sensors may be located external to the IMU, internal to the IMU, or any combination thereof. At least some sensors may use a structured light pattern for sensing.

Electronic system 1800 may include a display module 1860. Display module 1860 may be a near-eye display, and may graphically present information, such as images, videos, and various instructions, from electronic system 1800 to a user. Such information may be derived from one or more application modules 1822-1824, virtual reality engine 1826, one or more other hardware modules 1880, a combination thereof, or any other suitable means for resolving graphical content for the user (e.g., by operating system 1825). Display module 1860 may use LCD technology, LED technology (including, for example, OLED, ILED, μ-LED, AMOLED, TOLED, etc.), light emitting polymer display (LPD) technology, or some other display technology.

Electronic system 1800 may include a user input/output module 1870. User input/output module 1870 may allow a user to send action requests to electronic system 1800. An action request may be a request to perform a particular action. For example, an action request may be to start or end an application or to perform a particular action within the application. User input/output module 1870 may include one or more input devices. Example input devices may include a touchscreen, a touch pad, microphone(s), button(s), dial(s), switch(es), a keyboard, a mouse, a game controller, or any other suitable device for receiving action requests and communicating the received action requests to electronic system 1800. In some embodiments, user input/output module 1870 may provide haptic feedback to the user in accordance with instructions received from electronic system 1800. For example, the haptic feedback may be provided when an action request is received or has been performed.

Electronic system 1800 may include a camera 1850 that may be used to take photos or videos of a user, for example, for tracking the user's eye position. Camera 1850 may also be used to take photos or videos of the environment, for example, for VR, AR, or MR applications. Camera 1850 may include, for example, a complementary metal-oxide-semiconductor (CMOS) image sensor with a few millions or tens of millions of pixels. In some implementations, camera 1850 may include two or more cameras that may be used to capture 3-D images.

In some embodiments, electronic system 1800 may include a plurality of other hardware modules 1880. Each of other hardware modules 1880 may be a physical module within electronic system 1800. While each of other hardware modules 1880 may be permanently configured as a structure, some of other hardware modules 1880 may be temporarily configured to perform specific functions or temporarily activated. Examples of other hardware modules 1880 may include, for example, an audio output and/or input module (e.g., a microphone or speaker), a near field communication (NFC) module, a rechargeable battery, a battery management system, a wired/wireless battery charging system, etc. In some embodiments, one or more functions of other hardware modules 1880 may be implemented in software.

In some embodiments, memory 1820 of electronic system 1800 may also store a virtual reality engine 1826. Virtual reality engine 1826 may execute applications within electronic system 1800 and receive position information, acceleration information, velocity information, predicted future positions, or any combination thereof of the HMD device from the various sensors. In some embodiments, the information received by virtual reality engine 1826 may be used for producing a signal (e.g., display instructions) to display module 1860. For example, if the received information indicates that the user has looked to the left, virtual reality engine 1826 may generate content for the HMD device that mirrors the user's movement in a virtual environment. Additionally, virtual reality engine 1826 may perform an action within an application in response to an action request received from user input/output module 1870 and provide feedback to the user. The provided feedback may be visual, audible, or haptic feedback. In some implementations, processor(s) 1810 may include one or more GPUs that may execute virtual reality engine 1826.

In various implementations, the above-described hardware and modules may be implemented on a single device or on multiple devices that can communicate with one another using wired or wireless connections. For example, in some implementations, some components or modules, such as GPUs, virtual reality engine 1826, and applications (e.g., tracking application), may be implemented on a console separate from the head-mounted display device. In some implementations, one console may be connected to or support more than one HMD.

In alternative configurations, different and/or additional components may be included in electronic system 1800. Similarly, functionality of one or more of the components can be distributed among the components in a manner different from the manner described above. For example, in some embodiments, electronic system 1800 may be modified to include other system environments, such as an AR system environment and/or an MR environment.

The methods, systems, and devices discussed above are examples. Various embodiments may omit, substitute, or add various procedures or components as appropriate. For instance, in alternative configurations, the methods described may be performed in an order different from that described, and/or various stages may be added, omitted, and/or combined. Also, features described with respect to certain embodiments may be combined in various other embodiments. Different aspects and elements of the embodiments may be combined in a similar manner. Also, technology evolves and, thus, many of the elements are examples that do not limit the scope of the disclosure to those specific examples.

Specific details are given in the description to provide a thorough understanding of the embodiments. However, embodiments may be practiced without these specific details. For example, well-known circuits, processes, systems, structures, and techniques have been shown without unnecessary detail in order to avoid obscuring the embodiments. This description provides example embodiments only, and is not intended to limit the scope, applicability, or configuration of the invention. Rather, the preceding description of the embodiments will provide those skilled in the art with an enabling description for implementing various embodiments. Various changes may be made in the function and arrangement of elements without departing from the spirit and scope of the present disclosure.

Also, some embodiments were described as processes depicted as flow diagrams or block diagrams. Although each may describe the operations as a sequential process, many of the operations may be performed in parallel or concurrently. In addition, the order of the operations may be rearranged. A process may have additional steps not included in the figure. Furthermore, embodiments of the methods may be implemented by hardware, software, firmware, middleware, microcode, hardware description languages, or any combination thereof. When implemented in software, firmware, middleware, or microcode, the program code or code segments to perform the associated tasks may be stored in a computer-readable medium such as a storage medium. Processors may perform the associated tasks.

It will be apparent to those skilled in the art that substantial variations may be made in accordance with specific requirements. For example, customized or special-purpose hardware might also be used, and/or particular elements might be implemented in hardware, software (including portable software, such as applets, etc.), or both. Further, connection to other computing devices such as network input/output devices may be employed.

With reference to the appended figures, components that can include memory can include non-transitory machine-readable media. The term “machine-readable medium” and “computer-readable medium” may refer to any storage medium that participates in providing data that causes a machine to operate in a specific fashion. In embodiments provided hereinabove, various machine-readable media might be involved in providing instructions/code to processing units and/or other device(s) for execution. Additionally or alternatively, the machine-readable media might be used to store and/or carry such instructions/code. In many implementations, a computer-readable medium is a physical and/or tangible storage medium. Such a medium may take many forms, including, but not limited to, non-volatile media, volatile media, and transmission media. Common forms of computer-readable media include, for example, magnetic and/or optical media such as compact disk (CD) or digital versatile disk (DVD), punch cards, paper tape, any other physical medium with patterns of holes, a RAM, a programmable read-only memory (PROM), an erasable programmable read-only memory (EPROM), a FLASH-EPROM, any other memory chip or cartridge, a carrier wave as described hereinafter, or any other medium from which a computer can read instructions and/or code. A computer program product may include code and/or machine-executable instructions that may represent a procedure, a function, a subprogram, a program, a routine, an application (App), a subroutine, a module, a software package, a class, or any combination of instructions, data structures, or program statements.

Those of skill in the art will appreciate that information and signals used to communicate the messages described herein may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Terms, “and” and “or” as used herein, may include a variety of meanings that are also expected to depend at least in part upon the context in which such terms are used. Typically, “or” if used to associate a list, such as A, B, or C, is intended to mean A, B, and C, here used in the inclusive sense, as well as A, B, or C, here used in the exclusive sense. In addition, the term “one or more” as used herein may be used to describe any feature, structure, or characteristic in the singular or may be used to describe some combination of features, structures, or characteristics. However, it should be noted that this is merely an illustrative example and claimed subject matter is not limited to this example. Furthermore, the term “at least one of” if used to associate a list, such as A, B, or C, can be interpreted to mean any combination of A, B, and/or C, such as A, AB, AC, BC, AA, ABC, AAB, AABBCCC, etc.

Further, while certain embodiments have been described using a particular combination of hardware and software, it should be recognized that other combinations of hardware and software are also possible. Certain embodiments may be implemented only in hardware, or only in software, or using combinations thereof. In one example, software may be implemented with a computer program product containing computer program code or instructions executable by one or more processors for performing any or all of the steps, operations, or processes described in this disclosure, where the computer program may be stored on a non-transitory computer readable medium. The various processes described herein can be implemented on the same processor or different processors in any combination.

Where devices, systems, components or modules are described as being configured to perform certain operations or functions, such configuration can be accomplished, for example, by designing electronic circuits to perform the operation, by programming programmable electronic circuits (such as microprocessors) to perform the operation such as by executing computer instructions or code, or processors or cores programmed to execute code or instructions stored on a non-transitory memory medium, or any combination thereof. Processes can communicate using a variety of techniques, including, but not limited to, conventional techniques for inter-process communications, and different pairs of processes may use different techniques, or the same pair of processes may use different techniques at different times.

The specification and drawings are, accordingly, to be regarded in an illustrative rather than a restrictive sense. It will, however, be evident that additions, subtractions, deletions, and other modifications and changes may be made thereunto without departing from the broader spirit and scope as set forth in the claims. Thus, although specific embodiments have been described, these are not intended to be limiting. Various modifications and equivalents are within the scope of the following claims.

What is claimed is:

1. A device comprising:
an array of micro-LEDs characterized by a first pitch; and
an array of micro-lenses on the array of micro-LEDs and characterized by a second pitch different from the first pitch, each micro-lens in the array of micro-lenses corresponding to a respective micro-LED in the array of micro-LEDs.

2. The device of claim 1, wherein each micro-lens in the array of micro-lenses is configured such that a chief ray of light from the corresponding micro-LED in the array of micro-LEDs after passing through the micro-lens propagates in a different respective direction.

3. The device of claim 1, wherein the first pitch is greater than the second pitch.

4. The device of claim 3, wherein a chief ray of light from each micro-LED in the array of micro-LEDs after passing through the corresponding micro-lens tilts in a respective direction towards a middle line of the device.

5. The device of claim 1, wherein:
the array of micro-LEDs includes a two-dimensional array of micro-LEDs;
the array of micro-lenses includes a two-dimensional array of micro-lenses; and
the first pitch and the second pitch are in a first dimension.

6. The device of claim 5, wherein:
the array of micro-LEDs is characterized by a third pitch in a second dimension;
the array of micro-lenses is characterized by a fourth pitch in the second dimension; and
the third pitch is different from the fourth pitch.

7. The device of claim 6, wherein the first pitch is different from the third pitch.

8. The device of claim 6, wherein the second pitch is different from the fourth pitch.

9. The device of claim 1, wherein the array of micro-lenses includes a dielectric material or an organic material.

10. The device of claim 9, wherein the dielectric material includes silicon oxide or silicon nitride.

11. The device of claim 1, wherein the array of micro-lenses includes an anti-reflective coating.

12. The device of claim 1, wherein the array of micro-lenses includes spherical micro-lenses or aspherical micro-lenses.

13. The device of claim 1, wherein each micro-lens in the array of micro-lenses is configured to collimate light from the corresponding micro-LED in the array of micro-LEDs.

14. The device of claim 1, wherein at least one of the first pitch or the second pitch varies across the device.

15. The device of claim 1, wherein the first pitch is lower than the second pitch.

16. The device of claim 1, wherein the first pitch is less than 10 μm.

17. The device of claim 1, wherein a linear dimension of each micro-lens in the array of micro-lenses is greater than a linear dimension of each micro-LED in the array of micro-LEDs.

18. A method comprising:
depositing a polymer layer on a dielectric layer of a micro-LED array, the micro-LED array characterized by a first pitch between centers of adjacent micro-LEDs;
patterning the polymer layer to form a polymer pattern, wherein the polymer pattern in the polymer layer is characterized by a second pitch different from the first pitch; and
reflowing the polymer pattern to form a micro-lens array in the polymer layer, the micro-lens array characterized by a third pitch equal to the second pitch.

19. The method of claim 18, further comprising:
etching the micro-lens array in the polymer layer and the dielectric layer of the micro-LED array to form a micro-lens array in the dielectric layer,
wherein the polymer layer is characterized by an etch rate comparable to an etch rate of the dielectric layer.

20. The method of claim 18, wherein:
the polymer layer includes a photoresist layer; and
patterning the polymer layer comprises:
exposing the photoresist layer to exposure light through:
a gray-scale mask, wherein a light transmissivity profile of the gray-scale mask is complementary to a height profile of the micro-lens array in the polymer layer; or
a binary mask having a light transmissivity pattern corresponding to the polymer pattern in the polymer layer; and
developing the photoresist layer using a photoresist developer to remove exposed portions of the photoresist layer.
